(19) United States
(12) Patent Application Publication
(10) Pub. No.: US 2013/0105881 A1
(43) Pub. Date: May 2, 2013

(54) Self-Aligned Planar Flash Memory And Methods Of Fabrication

(71) Applicants: James K. Kai, Santa Clara, CA (US); Vinod R. Purayath, Santa Clara, CA (US); George Matamis, Danville, CA (US); Nima Mokhlesi, Los Gatos, CA (US); Cuong Trinh, Fremont, CA (US)

(72) Inventors: James K. Kai, Santa Clara, CA (US); Vinod R. Purayath, Santa Clara, CA (US); George Matamis, Danville, CA (US); Nima Mokhlesi, Los Gatos, CA (US); Cuong Trinh, Fremont, CA (US)

(21) Appl. No.: 13/646,500

(22) Filed: Oct. 5, 2012

Related U.S. Application Data
(60) Provisional application No. 61/553,057, filed on Oct. 28, 2011.

(51) Int. Cl. H01L 29/788; H01L 21/762; H01L 21/336

(52) U.S. Cl. 257/319; 438/258; 438/424; 257/E21.422; 257/E29.3; 977/943; 977/774; 257/E21.546

(57) ABSTRACT

A non-volatile memory fabrication process includes the formation of a complete memory cell layer stack before isolation region formation. The memory cell layer stack includes an additional place holding control gate layer. After forming the layer stack columns, the additional control gate layer will be incorporated between an overlying control gate layer and underlying intermediate dielectric layer. The additional control gate layer is self-aligned to isolation regions between columns while the overlying control gate layer is etched into lines for contact to the additional control gate layer. In one embodiment, the placeholder control gate layer facilitates a contact point to the overlying control gate layer such that contact between the control gate layers and the charge storage layer is not required for select gate formation.

### PRIORITY CLAIM

The present application claims priority from U.S. Provisional Patent Application No. 61/553,057, entitled “SELF-ALIGNED PLANAR FLASH MEMORY CELL AND METHODS OF FABRICATION,” by Kai, et al., filed Oct. 28, 2011, which is incorporated by reference herein in its entirety.

### BACKGROUND OF THE INVENTION

1. Field of the Invention

Embodiments of the present disclosure are directed to high density semiconductor devices, such as non-volatile memory, and methods of forming the same.

2. Description of the Related Art

In most integrated circuit applications, the substrate area allocated to implement the various integrated circuit functions continues to decrease. Semiconductor memory devices, for example, and their fabrication processes are continuously evolving to meet demands for increases in the amount of data that can be stored in a given area of the silicon substrate. These demands seek to increase the storage capacity of a given size of memory card or other type of package and/or decrease their size.

Electrical Erasable Programmable Read Only Memory (EEPROM), including flash EEPROM, and Electronically Programmable Read Only Memory (EPROM) are among the most popular non-volatile semiconductor memories. One popular flash EEPROM architecture utilizes a NAND array having a large number of strings of memory cells connected through one or more select transistors between individual bit lines and common source lines. FIG. 1 is a top view showing a single NAND string and FIG. 2 is an equivalent circuit thereof. The NAND string depicted in FIGS. 1 and 2 includes four transistors 100, 102, 104 and 106 in series between a first select gate 120 and a second select gate 122. Select gate 120 connects the NAND string to a bit line via bit line contact 126. Select gate 122 connects the NAND string to a common source line via source line contact 128. Each of the transistors 100, 102, 104 and 106 is an individual storage element and includes a control gate and a floating gate. For example, transistor 100 includes control gate 100CG and floating gate 100FG, transistor 102 includes control gate 102CG and floating gate 102FG, transistor 104 includes control gate 104CG and floating gate 104FG, and transistor 106 includes control gate 106CG and floating gate 106FG. Control gate 100CG is connected to word line WL3, control gate 102CG is connected to word line WL2, control gate 104CG is connected to word line WL1, and control gate 106CG is connected to word line WL0.

Note that although FIGS. 1 and 2 show four memory cells in the NAND string, the use of four transistors is only provided as an example. A NAND string can have less than four memory cells or more than four memory cells. For example, some NAND strings will include eight memory cells, 16 memory cells, 32 memory cells, or more.

The charge storage elements of current flash EEPROM arrays are most commonly electrically conductive floating gates, typically formed from a doped polysilicon material. Other types of memory cells in flash EEPROM systems can utilize a non-conductive dielectric material in place of a conductive floating gate to form a charge storage element capable of storing charge in a non-volatile manner. More recently, nanostructure-based charge storage regions have been used to form the charge storage element such as a floating gate in non-volatile memory devices.

As demands for higher densities in integrated circuit applications have increased, fabrication processes have evolved to reduce the minimum feature sizes of circuit elements such as the gate and channel regions of transistors. As the feature sizes have decreased, modifications to the traditional memory array have been made to, among other things, decrease parasitic capacitances associated with small feature sizes. Existing fabrication techniques, however, may not be sufficient to fabricate integrated devices these devices.

### BRIEF DESCRIPTION OF THE DRAWINGS

FIG. 1 is a top view of a NAND string.

FIG. 2 is an equivalent circuit diagram of the NAND string depicted in FIG. 1.

FIG. 3 is a plan view of a portion of a NAND flash memory array.

FIG. 4 is an orthogonal cross-sectional view taken along line A-A of the portion of the flash memory array depicted in FIG. 3.

FIG. 5 is a three-dimensional drawing of a pair of four word line long portions of two NAND strings.

FIG. 6 is a block diagram depicting one embodiment of a portion of a memory array according to the technology described herein.

FIG. 7 is a block diagram depicting one embodiment of a portion of a memory array according to the technology described herein.

FIG. 8 is a flowchart describing a fabrication process for non-volatile storage according to one embodiment.

FIGS. 9A-9L are cross-sectional views of a portion of a non-volatile memory system depicting a fabrication process in accordance with one embodiment.

FIG. 10 is a flowchart describing a fabrication process for non-volatile storage according to one embodiment.

FIGS. 11A-11K are cross-sectional and top views of a portion of a non-volatile memory system depicting a fabrication process in accordance with one embodiment.

FIG. 12 is a block diagram depicting an example of a memory system.

FIG. 13 depicts one embodiment for organizing a memory array and supporting circuitry.

FIG. 14 depicts one embodiment for organizing a memory array and supporting circuitry.

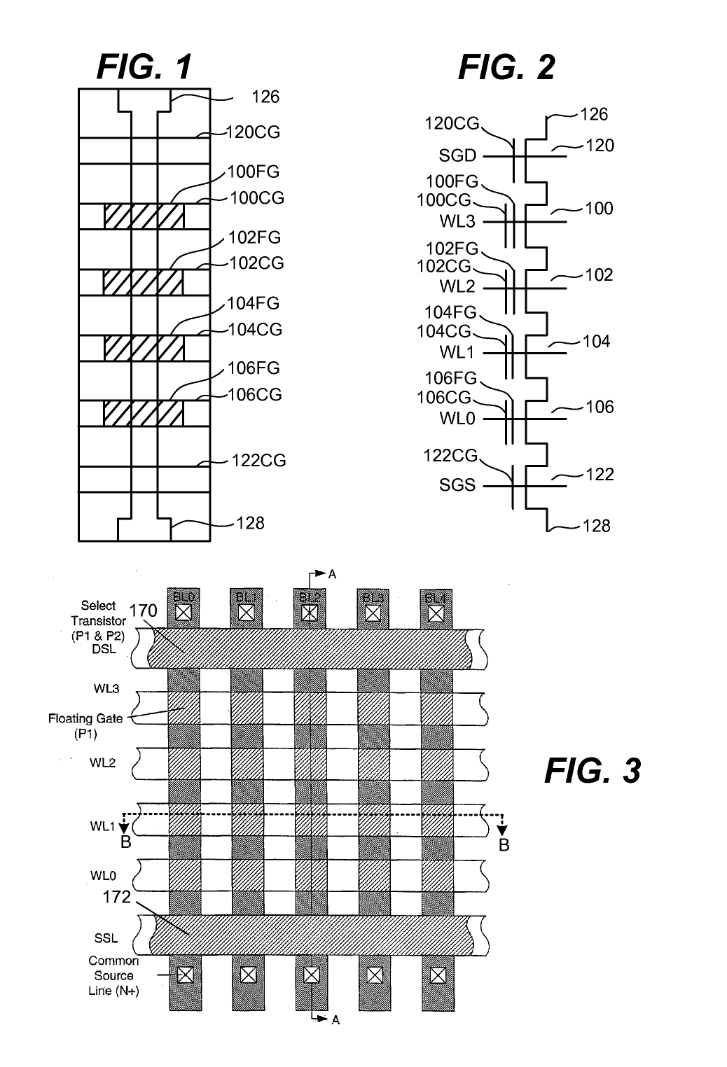

### DETAILED DESCRIPTION

Non-volatile memory systems and fabrication processes for these systems are disclosed. In one embodiment, a planar flash memory device is provided with a self-aligned storage element. Planar flash memory devices include at least one thin charge storage layer that presents an additional difficulty when attempting to contact an overlying control gate layer to form select gates for storage elements, by shorting the charge storage to the control gate layer for example. A fabrication process includes the formation of a complete memory cell layer stack before isolation region formation. The memory cell layer stack includes an additional place holding control gate layer. After forming the layer stack columns, the additional control gate layer will be incorporated between an overlying control gate layer and underlying intermediate dielectric layer. The additional control gate layer is self-aligned to isolation regions between columns while the overlying control gate layer is etched into lines for contact to the additional control gate layer. In one embodiment, the placeholder control gate layer facilitates a contact point to the overlying control gate layer such that contact between the control gate layers and the charge storage layer is not required for select gate formation.

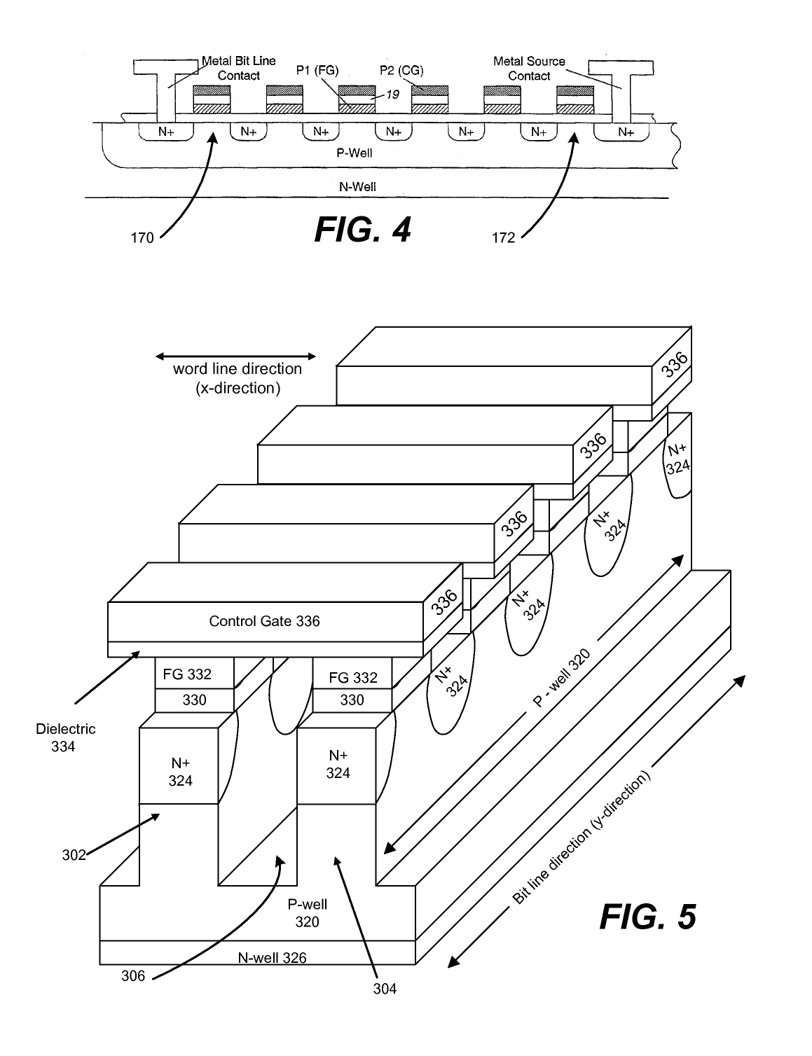

An example of one type of memory system that can be fabricated in accordance with one embodiment is shown in plan view in FIG. 3. BL0-BL4 represent bit line connections to global vertical metal bit lines (not shown). Four floating gate memory cells are shown in each string by way of example. Typically, the individual strings include 16, 32 or more memory cells, forming a column of memory cells. Control gate (word) lines labeled WL0-WL3 extend across multiple strings over rows of floating gates, often in polysilicon. FIG. 4 is a cross-sectional view taken along line A-A of FIG. 3, depicting polysilicon layer P2 from which the control gate lines are formed. The control gate lines are typically formed over the floating gates as a self-aligned stack, and are capacitively coupled to the floating gates through an intermediate dielectric layer 162. The top and bottom of the string connect to a bit line and a common source line through select transistors (gates) 170 and 172, respectively. Gate 170 is controlled by selection line DSL and gate 172 is controlled by selection line SSL. The floating gate material (P1) can be shorted to the control gate for the select transistors to be used as the active gate. Capacitive coupling between the floating gate and the control gate allows the voltage of the floating gate to be raised by increasing the voltage on the control gate. An individual cell within a column is read and verified during programming by causing the remaining cells in the string to be turned on hard by placing a relatively high voltage on their respective word lines and by placing a relatively lower voltage on the one selected word line so that the current flowing through each string is primarily dependent only upon the level of charge stored in the addressed cell below the selected word line. That current typically is sensed for a large number of strings in parallel, in order to read charge level states along a row of floating gates in parallel. Examples of NAND memory cell array architectures and their operation as part of a memory system are found in U.S. Pat. Nos. 5,570,315, 5,774,397 and 6,046,935.

FIG. 5 is a three-dimensional block diagram of two exemplary NAND strings 302 and 304 that may be fabricated as part of a larger flash memory array. FIG. 5 depicts four memory cells on strings 302 and 304 as an example. FIG. 5 depicts N-well 326 below P-well 320. The bit line or y-direction runs along the NAND strings, and the word line or x-direction runs perpendicular to the NAND string or the bit line direction. The word line direction may also be referred to as the row direction and the bit line direction referred to as the column direction. The P-type substrate below N-well 336 is not shown in FIG. 5. In one embodiment, the control gates form the word lines. A continuous layer of conductive layer 336 can be formed which is consistent across a row in order to provide a common word line or control gate for each device on that word line. In such a case, this layer can be considered to form a control gate for each memory cell at the point where the layer overlaps a corresponding floating gate layer 332. In other embodiments, individual control gates can be formed and then interconnected by a separately formed word line.

When fabricating a NAND-type non-volatile memory system, including NAND strings as depicted in FIG. 5, electrical isolation is provided in the word line direction between adjacent strings. In the embodiment depicted in FIG. 5, NAND string 302 is separated from NAND string 304 by isolation area 306. In one embodiment, an insulating material or dielectric is formed between adjacent NAND strings in this isolation area. In another embodiment, air gaps are introduced in the column (bit line) and/or row (word line) direction to form electrical isolation between closely spaced components in the memory structure. Air gaps can decrease parasitic interferences between neighboring charge storage regions (e.g., floating gates), neighboring control gates and/or between neighboring floating and control gates. Air gaps can enhance coupling and boost ratios for programming non-volatile memory. Air gaps can include various material compositions and need not correspond to atmospheric air. For example, concentrations of elemental gases may vary in the air gap regions. An air gap is simply a void where no solid material is formed in the semiconductor structure.

In one embodiment, two NAND strings (or other grouping of memory cells) share a single bit line. Two NAND strings may share a bit line using two select gates at the drain side (same end) of each NAND string in order to connect or disconnect a NAND string from a bit line in one example. The select line (signal) SGD can be replaced by two select lines SGDE and SGDO. Each NAND string includes two drain side select gates, each connected to a different drain side selection signal. One of the two drain side select gates for each NAND string can be a depletion mode transistor with its threshold voltage lower than 0Vs. In another example, a single drain side select gate is used for each NAND string, with two drain side select lines or signals.

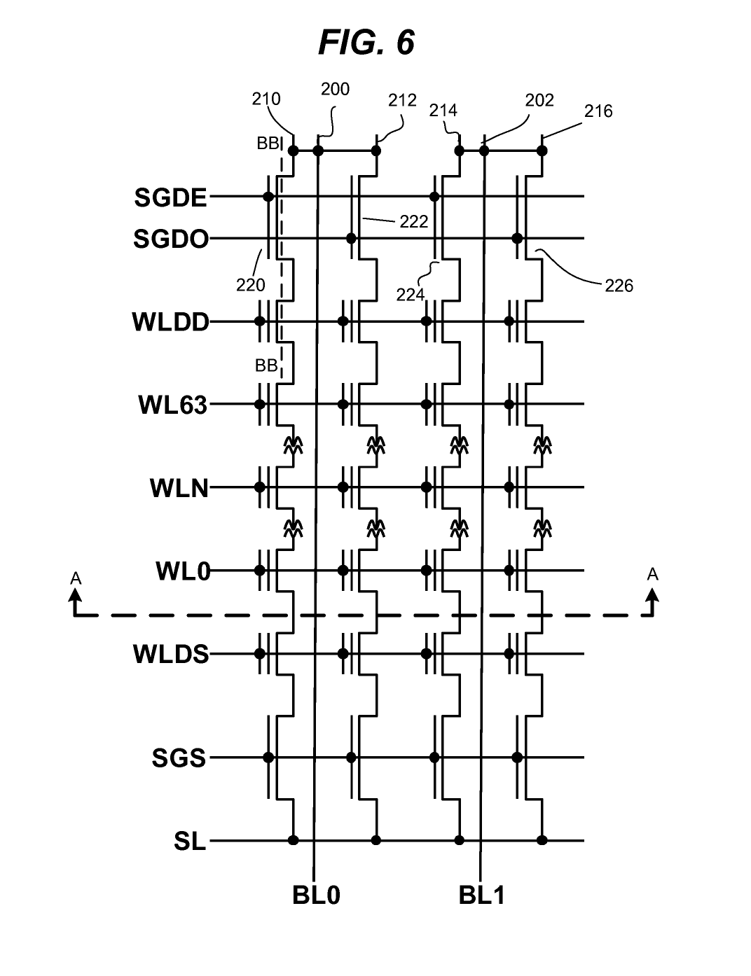

FIG. 6 shows an example with four NAND strings of a block of NAND strings. Each NAND string includes 64 data memory cells (WL0 . . . WL63) with one or more dummy memory cells on each side of the data memory cells. In other embodiments, more or less than 64 data memory cells can be included on a NAND string. The block of memory cells include two drain side select signals SGDE and SGDO. Bit line 200 is connected to NAND string 210 and NAND string 212. Bit line 202 is connected to NAND string 214 and NAND string 216. The drain side select signal SGDE is used to select or unselect NAND string 210 and NAND string 214. The drain side signal SGDO is used to select NAND string 212 and NAND string 216. Each NAND string only includes one drain side select gate, implemented as a single transistor. For example NAND string 210 includes drain side select gate 220, NAND string 212 includes drain side select gate 222, NAND string 214 includes drain side select gate 224 and NAND string 216 includes drain side select gate 226. Both select signals SGDE and SGDO are physically connected to select gate 220, select gate 222, select gate 224 and select gate 226. Select signal line SGDE is in electrical communication with select gate 210 and select gate 214, while being electrically insulated from select gate 222 and select gate 226. Select line SGDO is in electrical communication with select gate 222 and select gate 226, and electrically insulated from select gate 220 and select gate 224.

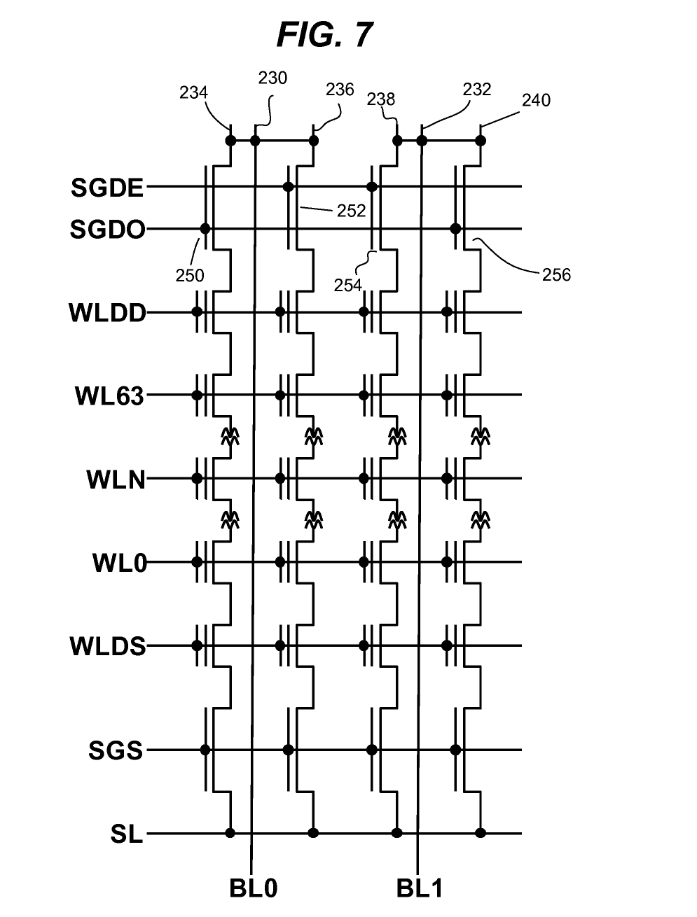

FIG. 7 shows another example where bit line 230 is connected to and shared by NAND string 234 and NAND string 236. Bit line 232 is connected to and shared by NAND string 238 and NAND string 240. Select lines SGDE and SGDO are physically connected to the select gates 250, 252, 254 and 256. Select line SGDE is in electrical communication with select gate 252 and select gate 254, while being electrically insulated from select gate 250 and select gate 256. Select line SGDO is in electrical communication with select gate 250 and select gate 256, while being electrically insulated from select gate 252 and select gate 254. In FIG. 6, each select line alternates between contacting and not contacting each select gate along a row such that every other NAND string has its select gate in electrical communication with the same select line. In FIG. 7, each select line alternates between contacting and not contacting pairs of select gates along a row such that adjacent pairs of NAND strings are in electrical communication with the same select line. Additional details regarding shared bit line architectures, including their fabrication and operation can be found in U.S. patent application Ser. No. 13/107,686 entitled, “NON-VOLATILE STORAGE SYSTEM WITH SHARED BIT LINES CONNECTED TO SINGLE SELECTION DEVICE,” filed May 13, 2011 and incorporated by reference herein in its entirety.

As devices continue to be scaled, reaching 2× and 1× nm feature sizes for example, there exists little space between floating gates adjacent in the row direction. A planar type of memory cell structure can be used with one or more intermediate dielectric layers and/or one or more control gate layers that do not wrap around the charge storage regions. The intermediate dielectric material and some portion of the control gate material is cut or discontinuous in the row direction.

The integration of planar memory cell technology with existing select gate and peripheral gate technology poses difficulties. Moreover, the further integration with devices that utilize non-traditional charge storage materials and/or shared bit line architectures poses a number of design challenges. For example, different charge storage materials may be used, including dielectric charge storage materials, metal and non-metal nanostructures (e.g., carbon), and hybrid combinations of these materials as a charge storage material. As earlier described, the different polysilicon layers P1 and P2 may be shorted together in traditional devices to form a select gate or peripheral transistor. With planar memory cells, non-traditional charge storage materials and/or shared bit line architectures, however, additional measures may be taken.

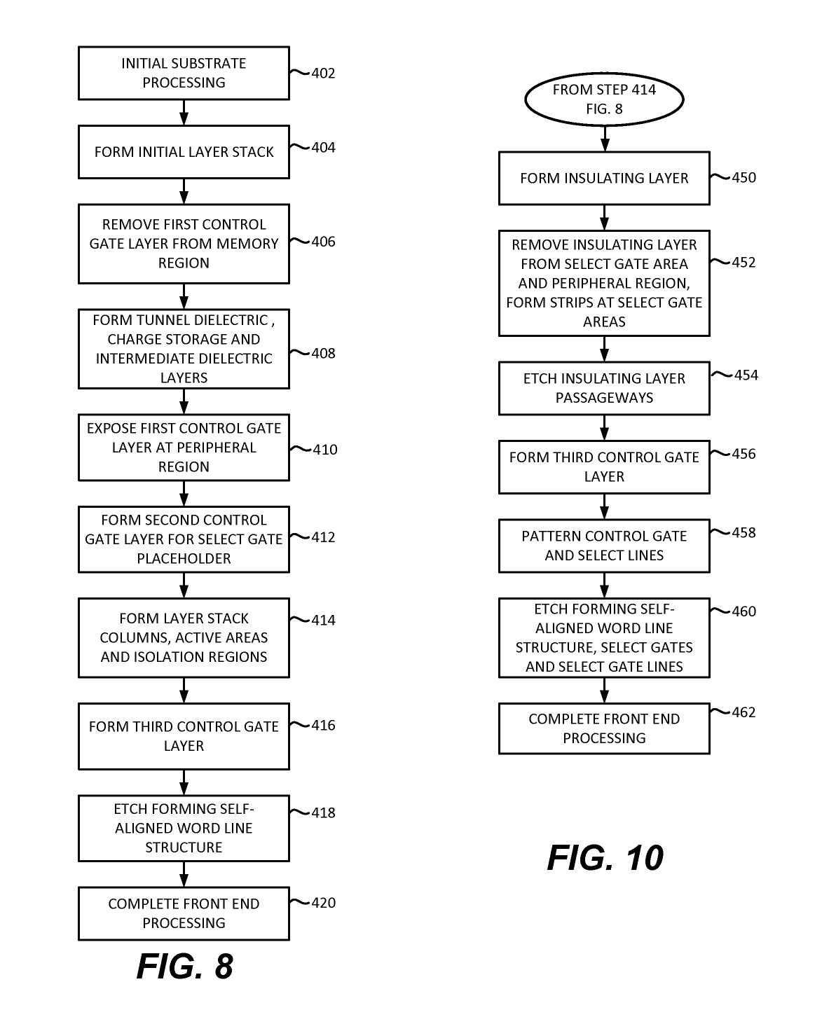

FIG. 8 is a flow chart describing a method of fabricating nonvolatile storage including a planar memory cell architecture in accordance with one embodiment. A full memory cell stack is formed including a sacrificial or placeholding control gate layer that is self-aligned to active areas and shallow trench isolation regions. While not required, the charge storage regions may include a nontraditional charge storage material such as a nano-structure-based charge storage component, metallic-based charge storage material or a dielectric-based charge storage material utilizing a charge trap mechanism. With these or polysilicon layers that are very thin, contact or shorting for select gate formation is avoided by incorporating a placeholding or sacrificial control gate layer.

At step 402 initial processing is performed to prepare a substrate for memory fabrication. One or more wells (e.g., a triple well) are typically formed in the substrate prior to forming a layer stack over the substrate surface. For example, a p-type substrate may be used. Within the p-type substrate an n-type well may be created, and within the n-type well a p-type well may be created. Various units of a memory array may be formed within individual p-type wells. The wells can be implanted and annealed to dope the substrate. A zero layer formation step may also precede well formation.

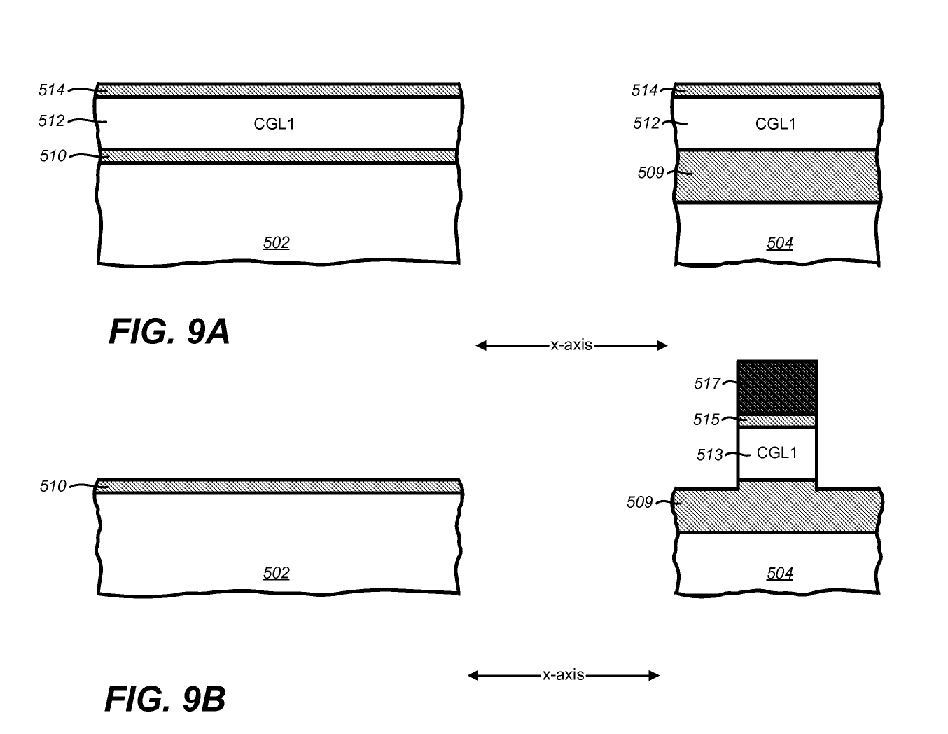

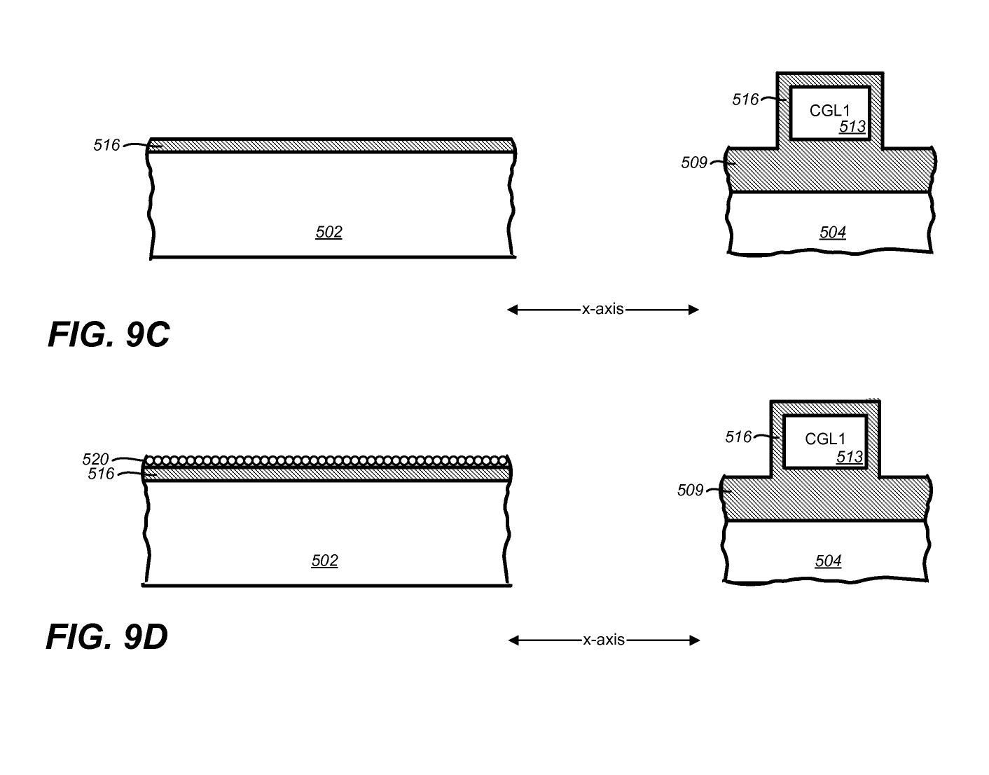

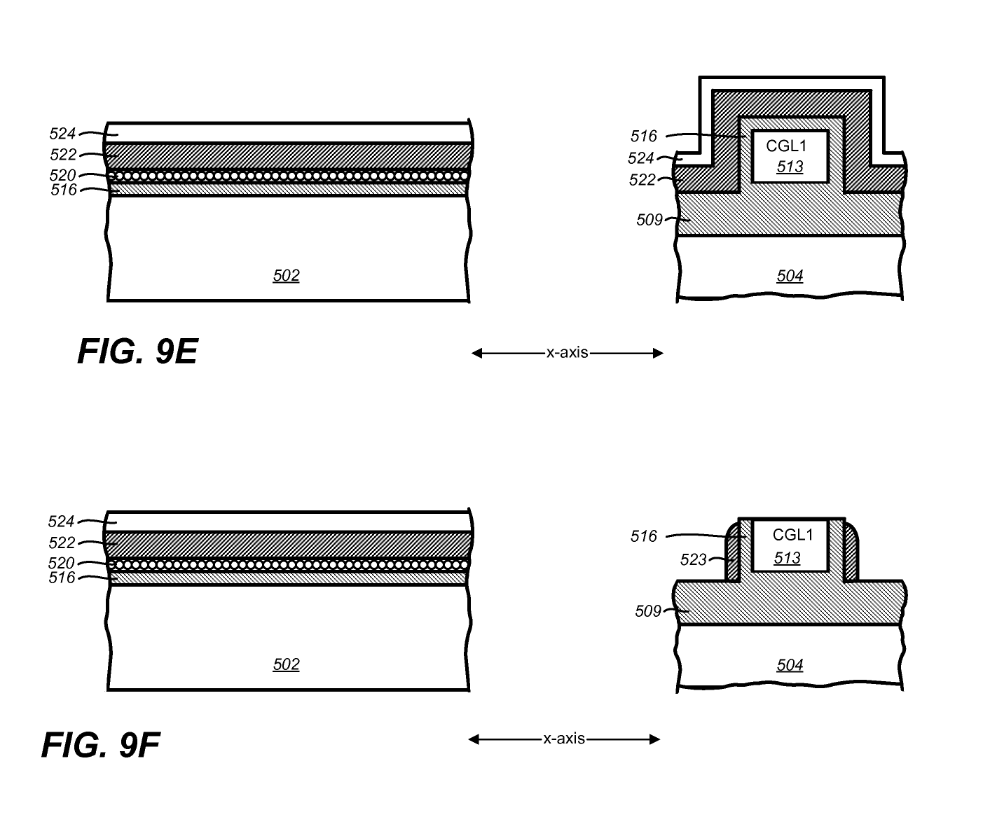

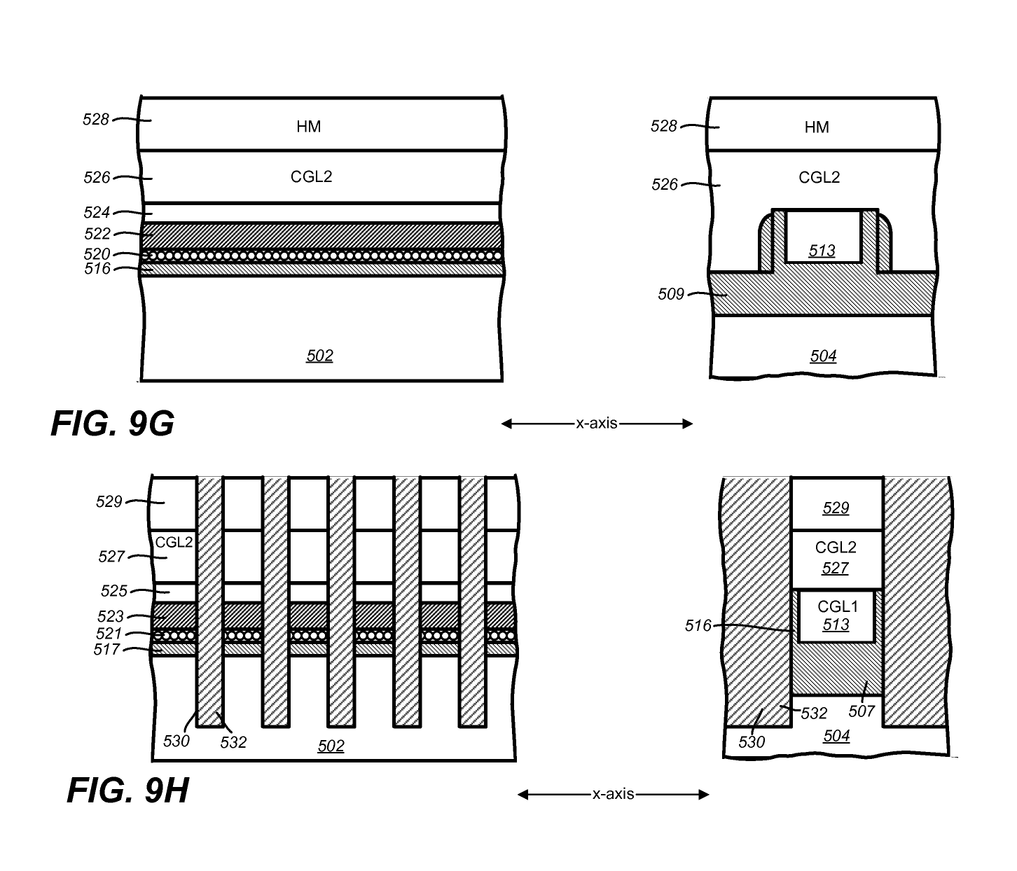

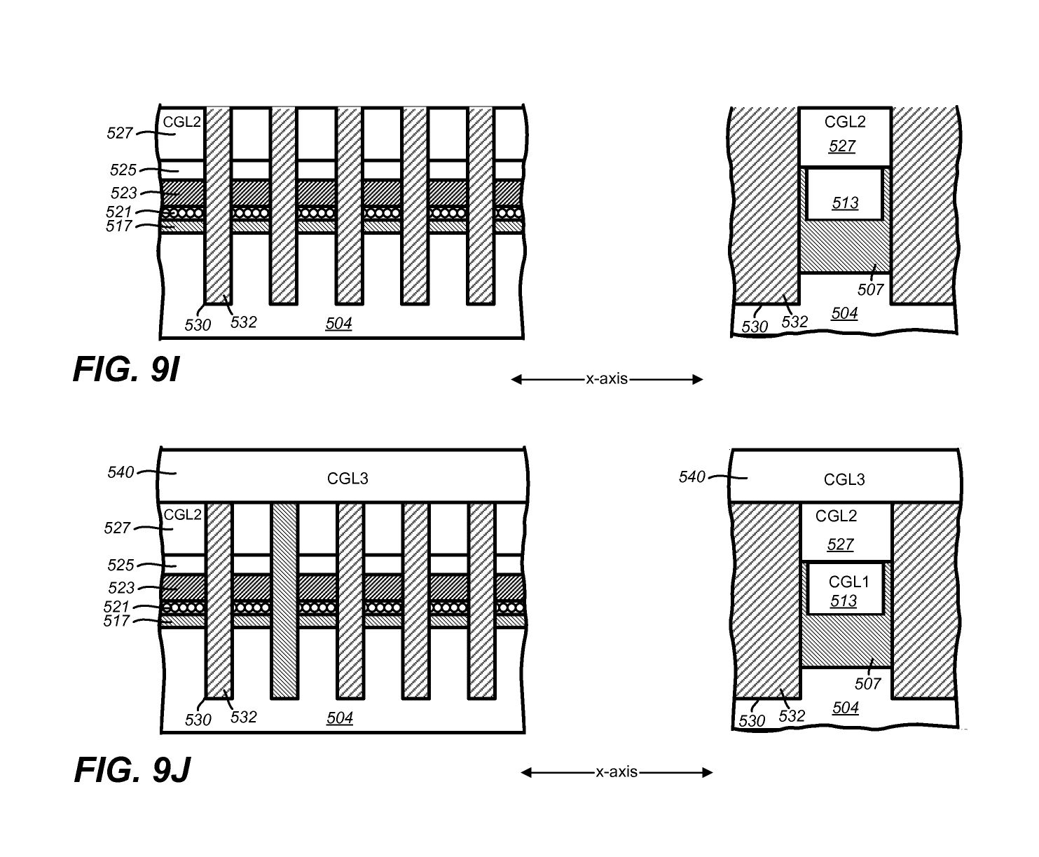

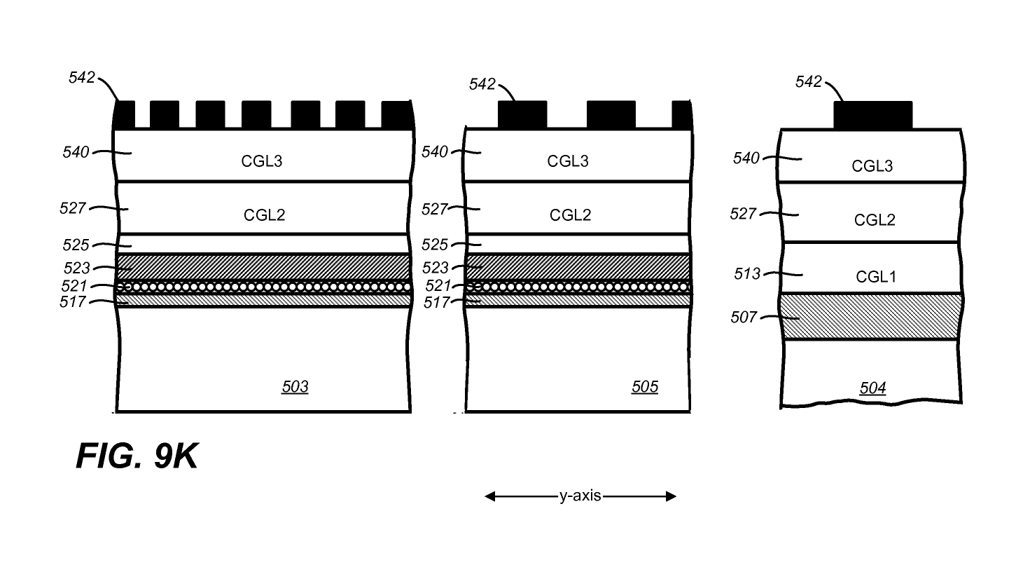

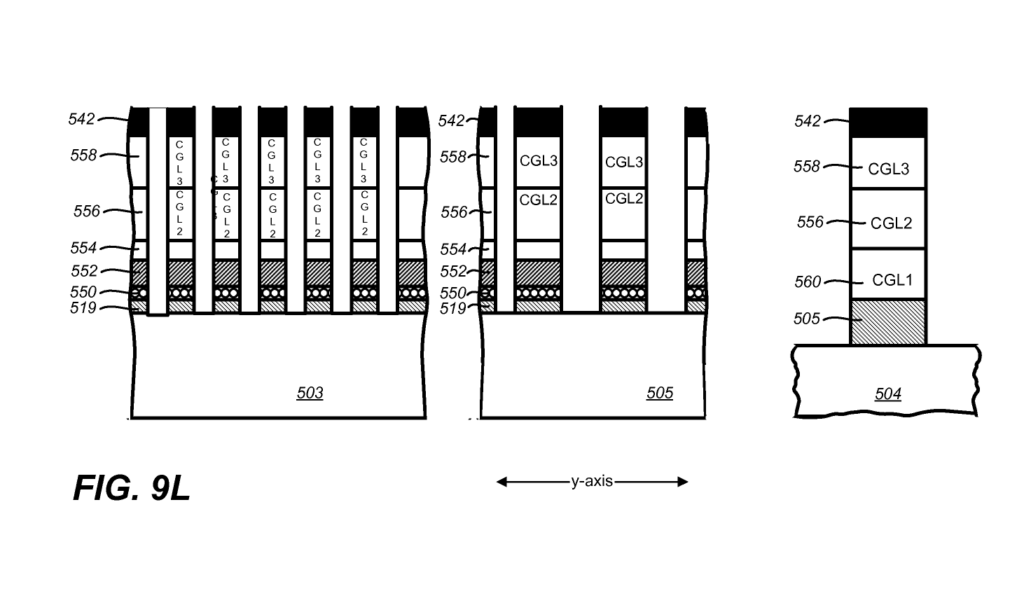

At step 404 an initial layer stack is formed over the substrate surface. FIG. 9A is a cross-sectional view along the x-axis in the row or word line direction of a memory array showing a layer stack formed over the surface of a substrate. The cross-sectional view in FIG. 9A corresponds to line B-B of FIG. 3 in one example or line A-A of FIG. 6 in another example. FIG. 9A depicts a memory region 502 and a peripheral circuitry region 504 of a substrate. Memory region 502 corresponds to a target region for the memory array and select gate transistors. The peripheral circuitry region 504 corresponds to a targeted region for one or more low voltage or high voltage peripheral transistors.

In this embodiment, the initial layer stack includes a first dielectric layer 510, a first control gate layer (CGL1) 512, and an oxidation layer 514. Oxidation layer 514 is formed by oxidizing the first control gate layer but is optional and is not included in other embodiments. It is noted that a layer may be said to be over another layer when one or more layers are between the two layers, as well as when the two layers are in direct contact.

The first dielectric layer 510 is a thin layer of oxide (For example, SiO₂) grown by thermal oxidation in one embodiment although different materials and processes can be used. Chemical vapor deposition (CVD) processes, metal organic CVD processes, physical vapor deposition (PVD) processes, atomic layer deposition (ALD) processes or other suitable techniques can be used to form the various labels described herein except where otherwise noted. In one example, the tunnel oxide layer is formed to a thickness of about nanometers (nm).

In this example, peripheral circuitry region 504 includes a high voltage gate dielectric region 509 that is formed in the substrate at the peripheral region 504. In one embodiment, a layer of silicon oxide is grown over the substrate followed by removing the oxide from any low voltage circuitry areas and memory region 502. A first dielectric layer 510 can then be formed over the substrate. In one example, the final thickness of dielectric region 509 is about 30 nanometers and includes portions of the first dielectric layer 510.

The first control gate layer 512 may include semi-conductor materials such a doped polysilicon or conductive materials such as metals, although any suitable conductive material can be used for the first control gate layer and the other control gate layers as described herein. In one embodiment, doped polysilicon is formed by low pressure chemical vapor deposition (LPCVD), although other processes can be used. In one example the first conductive layer is deposited to a depth of about 30 nanometers. Different thickness of the first conductive layer and any of the layers described herein may be used unless otherwise noted.

The control gate layer is polysilicon in one embodiment. The polysilicon can be doped in-situ or after formation. In another embodiment, the control gate layer is formed at least partially of a metal. In one example, the control gate layer has a lower portion that is formed from polysilicon and an upper portion that is formed from metal. A barrier layer may be formed between the polysilicon and the metal, to prevent silicidation. The control gate layer can include, by way of example (from layers to upper layers as move away from substrate surface): a barrier metal and metal; a barrier metal, polysilicon and silicide; a barrier metal and silicide (e.g., FUSI); polysilicon, a barrier metal and metal. Barrier metals may include, but are not limited to, Ti, TiN, WN and TaN or a combination with related alloys that have a suitable electron work function. Metals may include, but are not limited to, W, WSix or other similar low resistivity metals. Silicides may include, but are not limited to, NiSi, CoSi. In one example, the control gate layer is polysilicon that is subjected to silicidation after being etched into control gates so as to form a partially or fully-silicided control gate structures. The control gate layer may be formed by chemical vapor deposition (CVD), atomic layer deposition (ALD), plating, or another technique.

At step 406 the first control gate layer is removed from the memory region. FIG. 9B depicts the results of step 406 in one example. Conventional photolithography can be used to pattern one or more hard mask layers (not shown) into strips 517 at the target peripheral region 504. In the example of FIG. 9B, strip 517 is formed with a dimension in the x-axis direction than is less than that of the entire peripheral region, but in other examples the entire peripheral region may be covered with the mask material. Spacer assisted patterning, nano-imprint patterning and other patterning techniques can also be used to form strips of the hard mask layer at reduced feature sizes if needed. With masking strip 517 protecting the peripheral circuitry region layer stack, reactive ion etching or another suitable technique is used to remove oxidation layer 514 and the first control gate layer 512 from the memory region 502.

At step 408 a tunnel dielectric layer, charge storage layer and intermediate dielectric layer are formed over the substrate. FIGS. 9C through 9E depict processing in one example to form these layers. FIG. 9C depicts the formation of a tunnel dielectric layer 516 over the substrate surface at the memory region and vertically along the sidewalls of the strips 513 of the first control gate layer at the peripheral region. Before forming the tunnel dielectric layer in one example, an ashing step can be performed. A precleaning process can then be performed to remove any remaining portions of dielectric layer 510 followed by growing or depositing the tunnel dielectric layer 516 after removing hard mask strips 517. In one embodiment layer 516 is formed to a depth of six nanometers but other thicknesses can be used. FIG. 9D depicts a thin charge storage layer 520 formed over the tunnel dielectric layer 516 at the memory region. In one embodiment, the charge storage layer includes a nontraditional charge storage material including, but not limited to, a nanostructure coating, a metal layer, a hybrid polysilicon dielectric or metal layer, or a hybrid polysilicon nanostructure layer. The remaining discussion may describe layer 520 with respect to a nanostructure for convenience, but it will be understood that the fabrication is equally applicable to any charge storage material including traditional polysilicon-based floating gates.

In one example the nanostructure coating may include one or more nanostructure layers. In one embodiment the nanostructures are free of solvent in their formation, while in others the nanostructures are disbursed in one or more solvents. The nanostructures may form a disordered or ordered array such as an ordered monolayer or multilayer (e.g., spherical, polygonal). A solution of nanostructures can be formed by deposition processes including spin coating, dip coating, spraying, soaking and other techniques.

In one embodiment, a self-assembly process is used Self-assembly processes are capable of generating spatially regular structures. Self-assembling materials of block copolymers and nanostructures can form periodic patterns of nanostructures without etching. More information regarding nanostructures and their solutions can be found in U.S. application Ser. No. 11/958,875, entitled, “Method of Forming Memory with Floating Gates Including Self-Aligned Metal Nanodots Using a Polymer Solution,” by Purayath, et al., filed Apr. 5, 2010 and incorporated by reference herein in its entirety.

In one example, after deposition and self-assembly, the nanostructure coating is removed from the peripheral region 504. In another example, however, the nanostructure coating is not removed from the peripheral region and remains throughout the processing hereinafter as described. To selectively remove the nanostructure coating, the memory region is subject to ultraviolet curing without UV curing the peripheral region. Photoresist or another masking material can be applied over the peripheral circuitry region before applying UV light to the substrate surface. After selective curing the nanostructure layer, a rinse or wash can be applied to the wafer which will remove the nanostructure layer at locations where it has not been cured. This process results in removal of the nanostructure layer at the peripheral region. Other techniques can be used to remove the nanostructure layer from the peripheral region.

In self-assembly processes, photoactivatable compounds may be incorporated into a nanostructure solution for selective removal of the nanostructures from the select gate area. Where a coupling layer is used, the coupling layer material composition may be photoactivatable, such that the bond between the coupling layer and ligand or nanostructure is formed only upon exposure to light. Numerous photoactivatable compounds as known in the art may be used. By way of example, such compounds may include a phenyl azide group, which when photoactivated can from a covalent bond with, e.g., a silsesquioxane ligand comprising a coating associated with a surface of the nanostructures. Other photoactivatable compounds include an aryl azide group (e.g., a phenyl azide, hydroxphenyl azide, or nitrophenyl group), a psoralen, or a diene.

FIG. 9E depicts the formation of an intermediate dielectric layer 522 and barrier metal layer 524 at the memory region 502 and peripheral region 504. Intermediate dielectric layer 522 is a triple layer of oxide, nitride and oxide (ONO) in one embodiment having a thickness of about 9 to 12 nanometers, although various materials and thicknesses may be used. In one embodiment, a high-K dielectric constant material is used for the intermediate dielectric to reduce or eliminate charge transfer through the intermediate layer while providing enhanced control gate to floating gate coupling.

At step 410 the first control gate layer is exposed at the peripheral region. FIG. 9F depicts the results of step 410 in one embodiment. One or more hard masking layers and strips of photo resist can be formed at the cell region 502, leaving the peripheral region exposed. Reactive ion etching can be used to remove the barrier metal layer and intermediate dielectric layer from the peripheral region. In FIG. 9F etching intermediate dielectric layer 512 leaves spacers 523 along vertically extending portions of layer 516. In other examples all of the intermediate dielectric layer may be removed from the peripheral region during etching. It is noted that if a charge storage layer such as the nanostructure coating is left at the peripheral region it can be removed during etching at step 410.

At step 412 a second control gate layer is formed over the substrate. FIG. 9G depicts the results of step 412 in one example. A second control gate layer 526 (CGL2) is formed over the barrier metal layer 524 at the memory region 502. At peripheral region 504, the second control gate layer 526 overlies the gate dielectric region 509 and gate 513. The second control gate layer 526 serves as a placeholder for further processing at the memory region to fully form the planar memory cell structure. One or more hard masking layers 528 are formed over the second control gate layer. In one example, the second control gate layer is polysilicon formed to a depth of about 40 nanometers and the hard mask layers 528 are a layer of tetraorthosilicate (TEOS). In other examples, control gate materials as described above may be used.

At step 414 the layer stack is etched at the peripheral region 504 and memory region 502 to form layer stack columns, active areas and isolation regions. FIG. 9H depicts the results of step 414 in one embodiment. In one example, conventional photo lithography can be used to pattern the hard mask layer 528 into strips 529 elongated in the direction of the y-axis with spaces between strips adjacent in the direction of the x-axis. The hard mask layer may be patterned into a first subpattern at the memory region 502 and one or more different subpatterns at the peripheral region 504 to define active areas in the substrate with different dimensions in the x-axis direction. Spacer-assisted patterning, nano-imprint technology and other patterning techniques can also be used to form strips 529 of the hard mask at reduced feature sizes. The pattern, repetitive in the second or row direction, defines a first direction of etching to form columns of the targeted memory array. Each column includes a layer stack column elongated in the y-direction over an active area of the substrate between adjacent isolation regions.

FIG. 9H depicts each layer stack column at the memory regions 502 including a strip 517 of tunnel dielectric layer 516, a strip 521 of charge storage layer 520, a strip 523 of intermediate dielectric layer 522, a strip 525 of barrier metal layer 524, a strip 527 of second control gate layer 526, and a strip 529 of hard mask layer 528. At the peripheral region, each layer stack column includes a strip 507 of gate dielectric layer 509, a strip 513 of the first control gate layer, a strip 527 of the second control gate layer 526 and a strip 529 of the hard mask layer 528.

Etching the substrate forms a plurality of shallow isolation trenches 530. Each isolation trench 530 is filled with an insulating material 532 such as dielectric fill material (e.g., SiO2) formed by deposition and/or growth processes. The trenches and fill material form isolation regions that divide the substrate into isolated active areas underlying each layer stack column. The fill material is formed in the isolation trenches as well as the spaces between adjacent layer stack columns. Chemical mechanical planarization (CMP) or etch back processes are applied to create a substantially planar upper surface of the layer stacks at the peripheral and memory regions.

FIG. 9I depicts the results of chemical mechanical polishing to remove strips 529 of the hard mask layer and create a substantially planar upper surface of strips 527 of the second control gate layer separated by insulating material 532.

At step 416, a third control gate layer is formed over the substrate. FIG. 9J depicts the results of step 416 in one embodiment. A third control gate layer 540 (CGL3) is formed at the peripheral region 504 and memory region 502. In one example the third control gate layer 540 is a layer of polysilicon although different materials can be used as described for the other control gate layers.

At step 418 the memory region and peripheral region are patterned and etched to form a self-aligned word line structure defining gate lengths in the column direction for the storage elements, select gates and peripheral transistors. FIG. 9K depicts the results of forming a pattern including strips 542 of a hard masking material at the memory region 502 and peripheral region 504. A memory cell area 503 and select gate area 505 of memory region 502 are depicted. The strips 542 can be formed using traditional photolithography or by using nano-imprint or spacer-assisted technology to form devices at less than the minimally definable photolithography feature size. Strips 542 define an etch direction orthogonal to the direction of etching using the first pattern. The strips of hard masking material are elongated in the row direction along the x-axis with a spacing between strips in the column direction along the the y-axis. The pattern can be used to find the gate length for the charge storage region of each memory cell as well as the gate length for the select gates in area 505 and the gate length of the peripheral transistors at peripheral region 504. Strips 542 may include different dimensions at each area and region to define individually sized gates.

FIG. 9L depicts the results of etching using strips 542 as a pattern. Etching each layer stack column and insulating material 532 forms layer stacks rows at memory area 503. Each layer stack row includes a tunnel dielectric region 519, a charge storage region 550, an intermediate dielectric region 552, a barrier metal region 554, a control gate 556 formed from each strip 527 of the second control gate layer, and a strip 558 of the third control gate layer 540 elongated in the row direction. Strips 558 at the memory area can form word lines connected to individual control gates 556.

At the select gate area 505 a larger dimension in the y-axis direction is used for strips 542 to form select gates having a larger gate length in the y-axis direction. At the peripheral region, the gate dielectric strip 507 is etched into gate dielectric regions 505. Strip 513 of the first control gate layer are etched into a peripheral gate region 560 formed from the first control gate layer. The strip 527 of the second control gate layer is etched into a second control gate region 556 and the third control gate layer 540 is etched into a strip 558 of the third control gate layer that is elongated in the row direction to form a select line for the peripheral transistor.

FIG. 10 is a flow chart describing a process for fabricating nonvolatile storage in accordance with another embodiment. In FIG. 10 a planar memory cell is integrated with a shared bit line architecture having dual drain-side select gate lines. A sacrificial or placeholder control gate layer is incorporated into the memory region to facilitate a shared bit line for two adjacent NAND strings, with the second control gate layer defining a select gate length larger than the individual select gate lines. The fabrication is described with the further integration of a nanodot charge storage region (e.g., metallic or carbon), but other nontraditional charge storage materials or traditional polysilicon floating gates may be used.

Processing according to the method of FIG. 10 proceeds as described with respect to FIG. 8, including the formation of a complete memory cell stack before isolation region formation including a tunnel dielectric layer, charge storage layer, intermediate dielectric layer and at least one control gate layer. The initial layer stack and substrate are etched into layer stack columns, active areas and isolation regions as described at step 414.

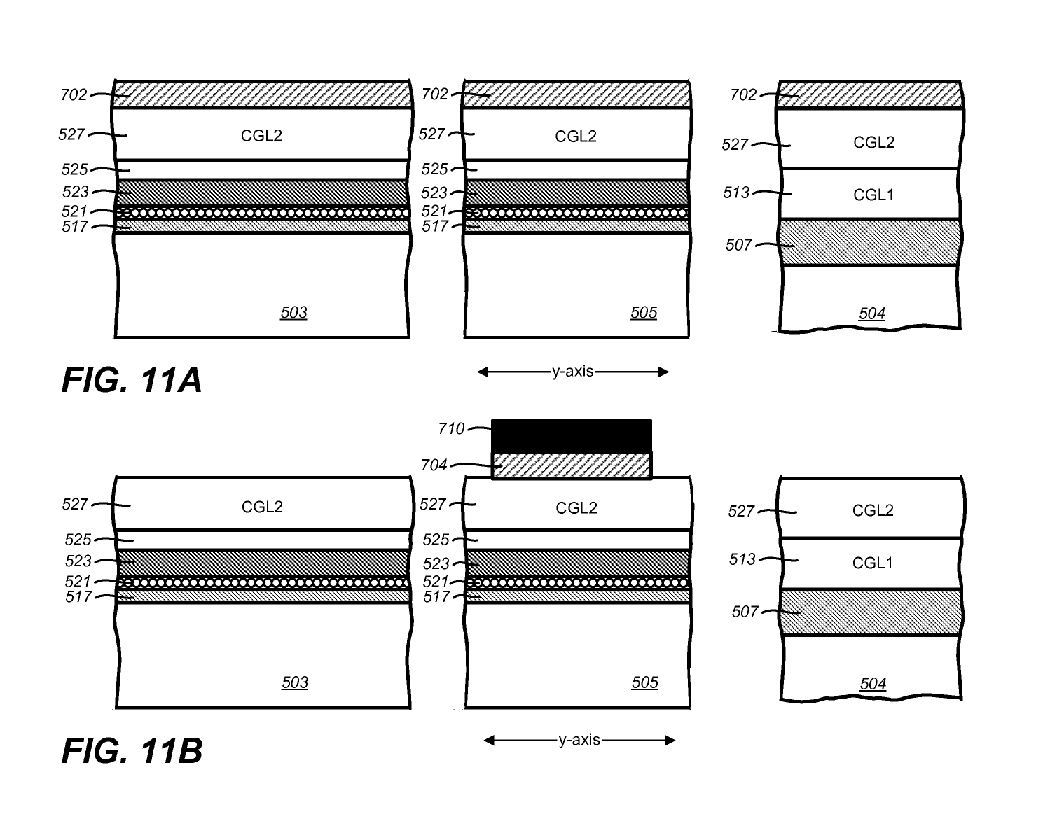

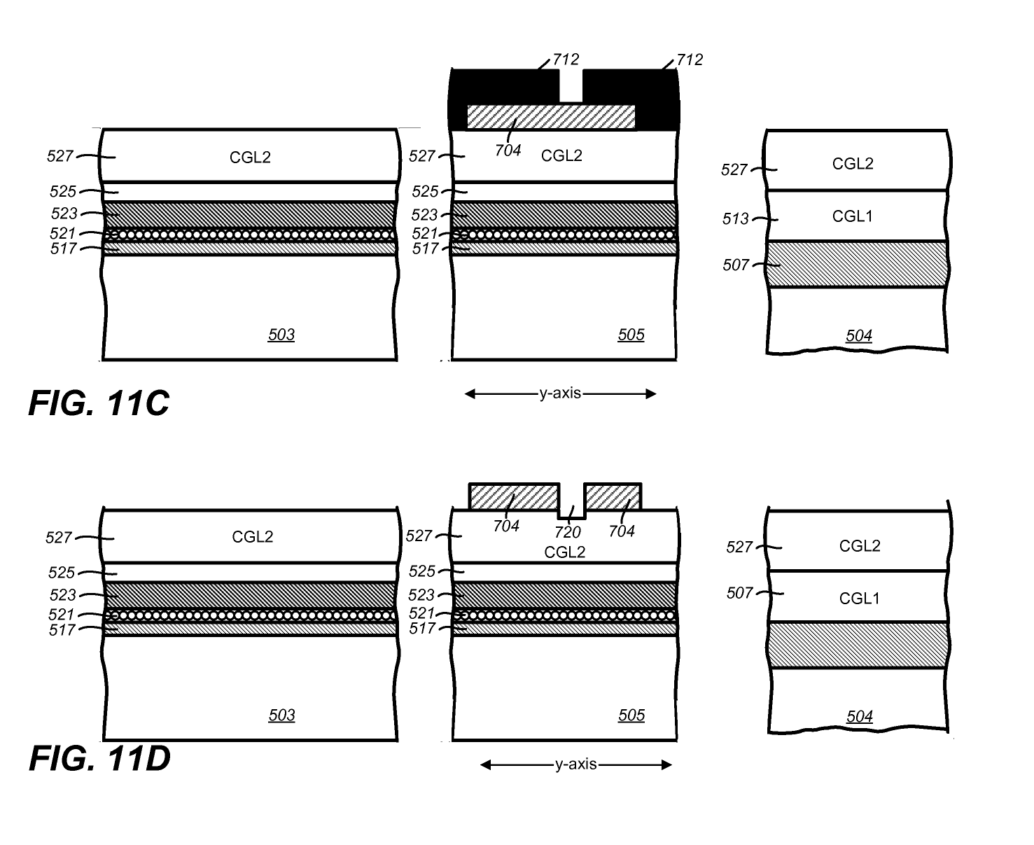

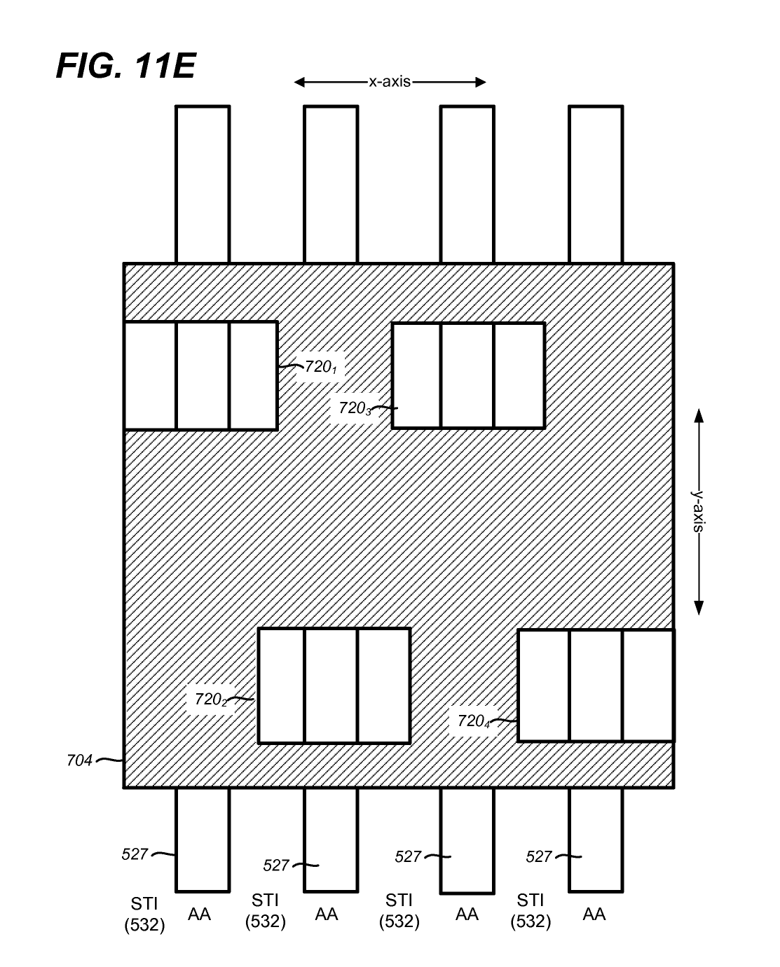

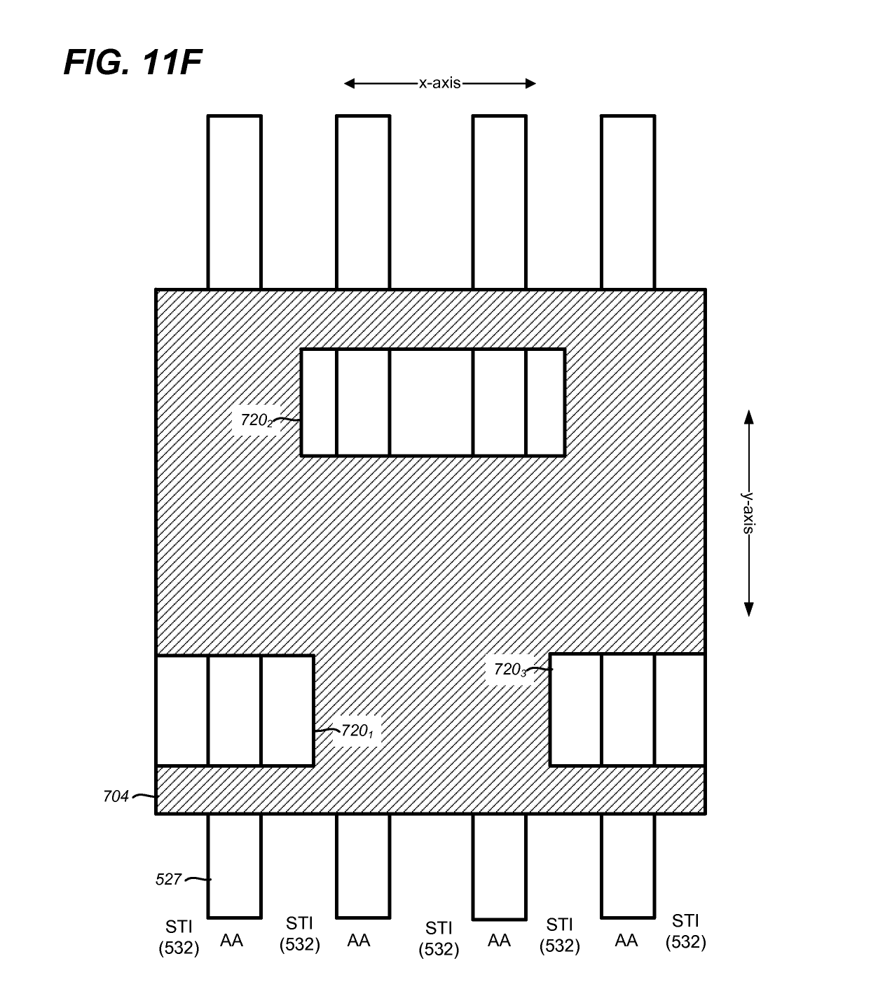

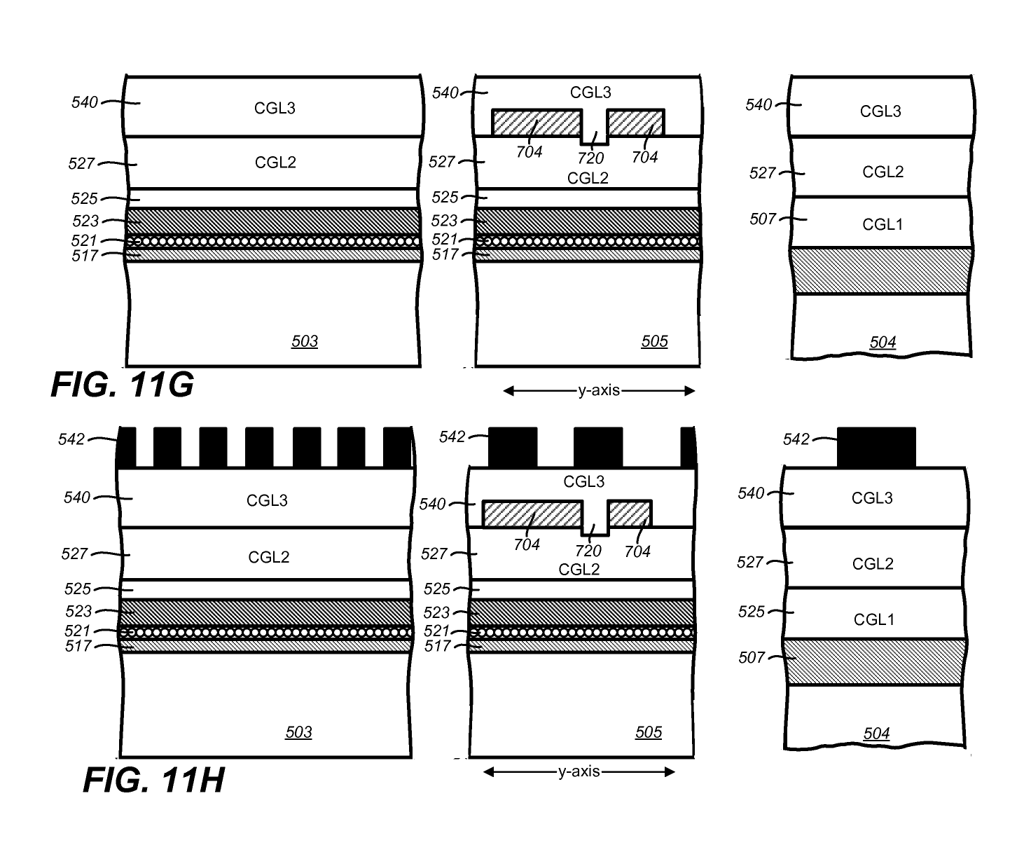

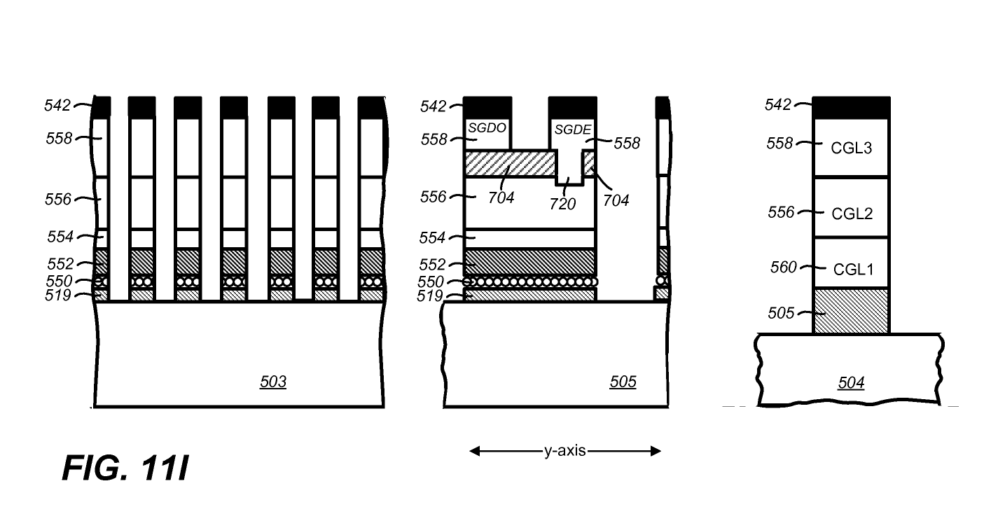

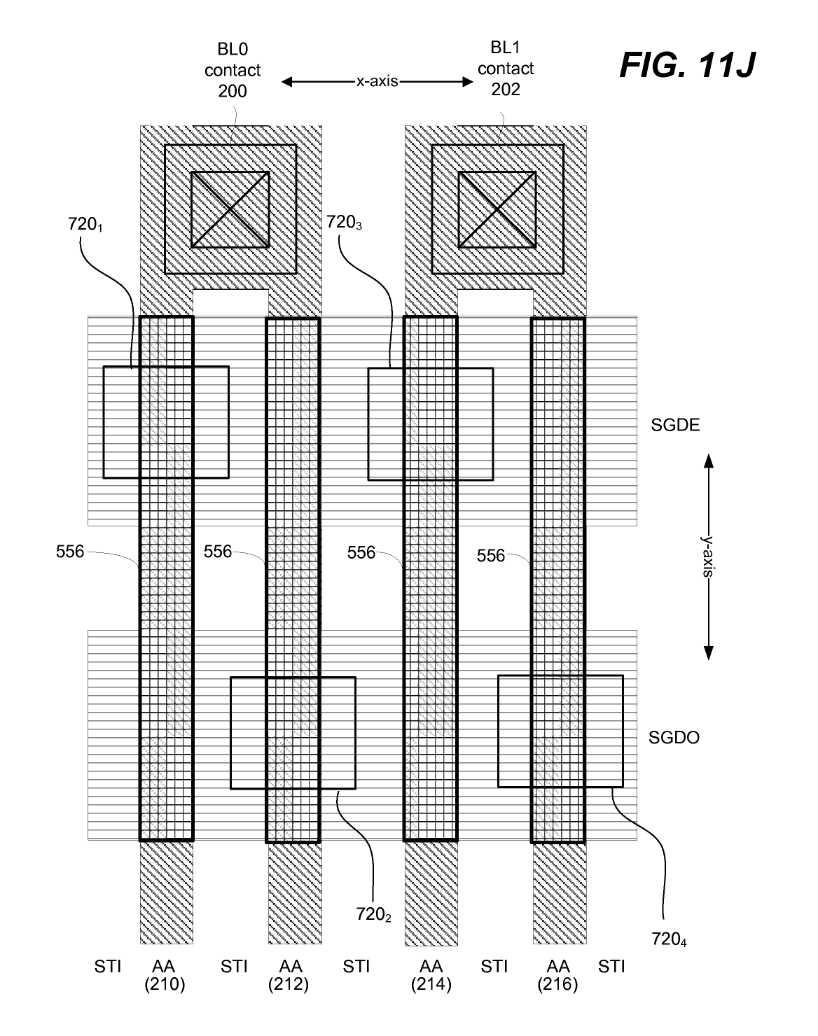

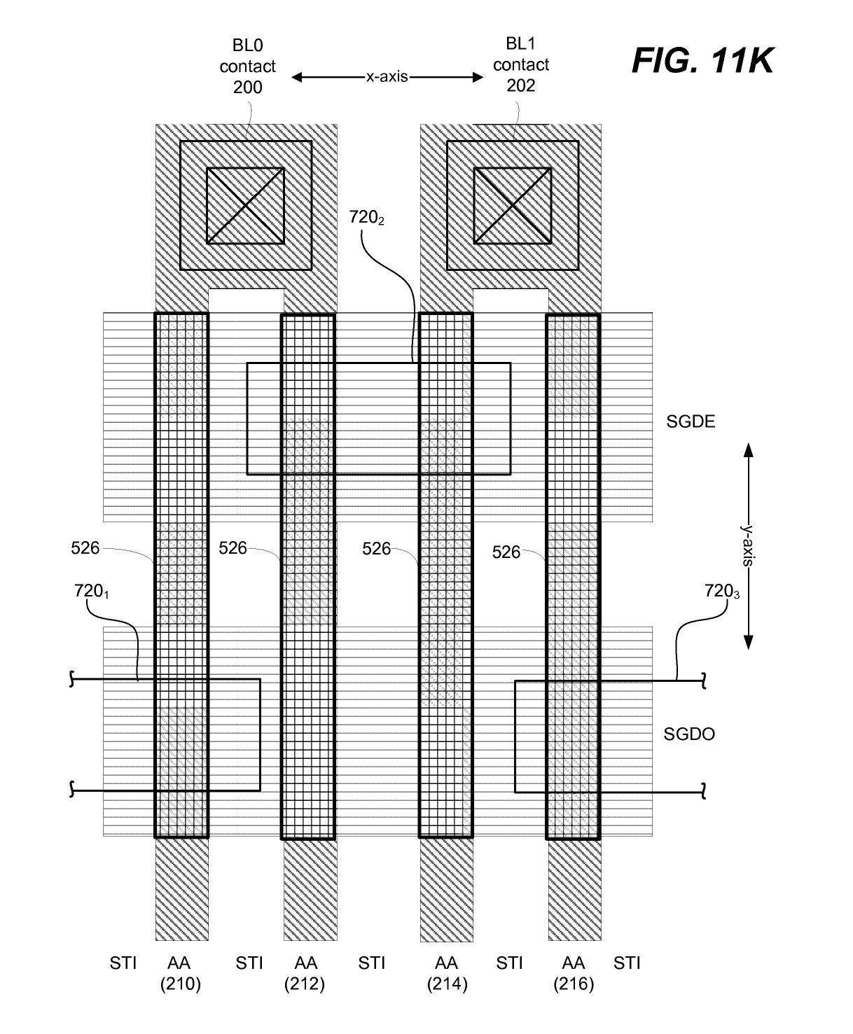

After forming the layer stack columns and polishing to form a planar upper surface, an insulating or other etch stop layer is formed at step 450 before forming a third control gate layer as at step 416 of FIG. 8. The insulating layer is a layer of oxide in one example, but other materials can be used. The insulating layer may provide selective etch capabilities with respect to the second control gate layer. FIG. 11A depicts the result of step 450 in one embodiment. At peripheral region 504, the layer stack includes the strip 507 of gate dielectric material 509, a strip 513 of the first control gate layer and a strip 527 of the second control gate layer. At the memory area 503 and select gate area 505, each layer stack column includes a strip 517 at the tunnel dielectric layer, a strip 521 of the charge storage layer, a strip 523 of the intermediate dielectric layer, a strip 525 of the barrier metal layer, a strip 527 of the second control gate layer, and an additional layer 702 of insulating material.

At step 452 the insulating layer is removed from the select gate area and peripheral region and is etched into a strip at the select gate area. FIG. 11B depicts the results of step 452 in one embodiment. Photolithography or other techniques can be used to pattern a hard mask layer and etch it into strip 710 at the select gate area. The hard mask layer may be patterned with a dimension in the column direction corresponding to a targeted gate length for each select gate. In another embodiment, the later formation of select gate line masks can be used to define the select gate length as described. After patterning the select gate area at step 454, the insulating layer is etched, completely removing the insulating material from the cell area 503 and peripheral region 504. Etching the insulating layer 702 at the select gate area removes portions of the insulating layer to form strips 704 having a dimension in the column direction corresponding to the targeted select gate length.

At step 456 passageways are etched into the insulating layer strips at the select gate area 505. FIGS. 11C to 11D depict processing to create passageways extending through insulating strip 704 to strips 527 of the second control gate layer. FIG. 11C depicts hard mask strips 712 for etching passageways into insulating layer strip 704. Traditional strips of photoresist or other patterning techniques may be used to pattern one or more hard masking layers to create strips 712. Using strip 712 as a mask, the strip of insulating material is etched as shown in FIG. 11D. Etching proceeds completely through the insulating material 704 to form passageways 720 that extend into strip 527 of the second control gate layer.

FIG. 11E is a top view of select gate area 505 in one example showing the results of step 456. Active areas AA are separated by isolation regions (STI) including fill material 532. The strip 704 of insulating material is depicted as extending across multiple active areas in the row direction. Passageways 720 have been formed in strips 704 exposing the underlying insulating material from the isolation regions and the strips 527 of the second control gate layer of each layer stack column.

The example of FIG. 11E corresponds to the shared bit line structure depicted in FIG. 6. In FIG. 11E, each passageway 720 has a dimension in the row direction along the x-axis that extends over a single active area so that a single contact to one underlying select gate is provided within each passageway 720. Each passageway alternates for each adjacent active area so that each resulting select line described hereinafter will contact alternating ones of the active areas to make alternate connections to select gates on every other active area.

FIG. 11F is a top view of an alternate embodiment corresponding to the shared bit line structure of FIG. 7. In this example, passageways 720 are created with a dimension in the row direction along the x-axis that extends over two active areas. In this manner each resulting select line as described hereinafter will contact a pair of adjacent select gate contacts for two adjacent active areas.

At step 456 a third control gate layer is formed over the substrate. FIG. 11G depicts the results of step 456 in one example. A third control gate layer 540 at the memory region extends fully over the second control gate layer strips 527. Similarly, at the peripheral region 504, the third control gate layer extends over each strip 527 of the second control gate layer. At select gate area 505, however, the third control gate layer 540 extends over exposed portions of the second control gate layer including those outside of the strip 704 of the insulating material as well as filling each passageway 720 created during step 456. In this matter the third control gate layer will extend between and through the insulating material strip 704 filling the passageways to create electrical communication at these points between the third control gate layer 540 and the strips 527 of the second control gate layer.

At step 458, the control gate and select lines are patterned at the memory area 503 and select gate area 505 as well as the peripheral transistor select lines at the peripheral region 504. FIG. 11H depicts the results of 460 in one example. Strips 542 of a hard mask or other material have been created using standard photolithography or other techniques as earlier described. At the memory area, strips 542 have a dimension in the direction of the y-axis corresponding to a target gate length for each storage element. At the select gate area each strip 542 has a target dimension in the y-axis corresponding to a target select gate line dimension for a single select gate line of a pair of select gate lines in the shared bit line architecture. That is, each strip 542 has a dimension in the direction of the y-axis corresponding to a select gate line dimension rather than a select gate dimension. As earlier described, each strip 704 of insulating material can have a dimension in the y-axis direction corresponding to the target select gate dimension. However, the dimension between outside edges of each strip 542 at the select gate area can be used to define the overall gate length from layer 527 as described below. Strips 542 at this point in processing are used to target each select gate line of a pair of select gate lines for the target shared bit line architecture. One strip 542 will overlie one row of passages 720 as shown in FIG. 11E or 11F and another strip will overlie another row of passages 720 as shown in FIGS. 11E and 11F.

At step 460 reactive ion etching or another suitable technique is used to etch through each layer stack column and isolation material separating them at the memory area 503 to form layer stack rows. FIG. 11I depicts the results of 462 in one example. Each layer stack row includes a strip 558 of the third control gate layer 540. A strip 556 of the second control gate layer 527 strips, a strip 554 of each strip 525 of the barrier metal layer, a strip 552 of each strip 523 of the intermediate dielectric layer, a charge storage of the region 550 formed from each strip 521 of the charge store's material and a tunnel dielectric region 519 formed from the strip 517 of tunnel dielectric material.

Notably at the select gate area 505, insulating material strip 704 provides an etch stop for the etching performed. Thus, etching proceeds through the third control gate layer forming strips 558 but stops upon hitting the strip 704 of insulating material. In this manner etching proceeds through the remaining material to form a select gate with a dimension in the y-axis direction corresponding to the line size of each strip 542 at the select gate area plus another strip 542 and the space in-between the two strips. As is illustrated, strips 558 form select gate lines SGDE and SGDO, respectively. In the example of FIG. 11H, line SGDO is depicted as overlying passageway 720 such that the third control gate material fills the passageway forming a connection point between line SGDE and the underlying strip 556 of the second control gate layer to form a contact at this point.

FIG. 11J is a top view of a portion of a final structure corresponding to the arrangement of FIG. 6 and FIG. 11E. Hard masking strips 542 and insulating layer 704 are not shown. Bit line contact 200 connects to a single bit line BL0 (not shown) for two adjacent active areas and hence, columns of memory cells. The second control gate layer strips 556 extend from the lower edge of SGDO to the upper edge of SGDE, defining a gate length for each select gate. Select line SGDE extends in the row direction across each active area and in this example, connects to alternate ones of the columns via passageways 720. Select line SGDE connects to active area 210 via passageway 720₁ and active area 214 via passageway 720₃. Each passageway connects SGDE to the second control gate layer 556 at these areas as earlier described. Passageway 720₁ provides a connection to strip 556 at active area 210 to define a first select gate for active area 210. The select gate length is defined by the dimension of strips 556 which extends in the y-axis or column direction from the lower edge of SGDO to the upper edge of SGDE. Thus, the gate length of the select gate is larger than the y-axis dimension of the select line SGDE. The other passageways define similar select gates at the other active areas.

Select line SGDO also extends in the row direction across each active area, connecting to alternate ones of the columns via passageways 720. Select line SGDO connects to active area 212 and active area 216 via passageways 720₂ and 720₄ to the second control gate layer strips 556.

In another embodiment of the structure of FIG. 6, an etch back step for the memory cells may be omitted or reduced around the drain side select gate such that the oxide that fills the STI region is at a higher level around the drain side select gate transistor area, thereby, reducing the overlay margins between the edge of the passageway and the appropriate control gate portion (SGDO or SGDE). That is, the passageway could be at the edge of the control gate region rather than in the middle. In another embodiment the signal lines SGDE and SGDO are narrower in the case when the etching process can selectively etch CGL1 and CGL2, without etching FG. In one example, this can be performed by having CGL1 and CGL2 comprise a first conductive material and the FG layer comprise a different conductive.

FIG. 11K is a top view of a portion of a structure corresponding to the embodiment of FIG. 7 and FIG. 11F. In this example, select line SGDE extends in the row direction across each active area and connects to alternate pairs of the columns via passageways 720. Select line SGDE connects to active area 212 and active area 214 via a single passageway 720₂ to the second control gate layer as earlier described. Select line SGDO also extends in the row direction across each active area, connecting to alternate ones of the columns via passageways 720₁ which connects to active area 210 and an adjacent active area not shown and passageway 720₃ which connects to active area 216 an adjacent active area not shown.

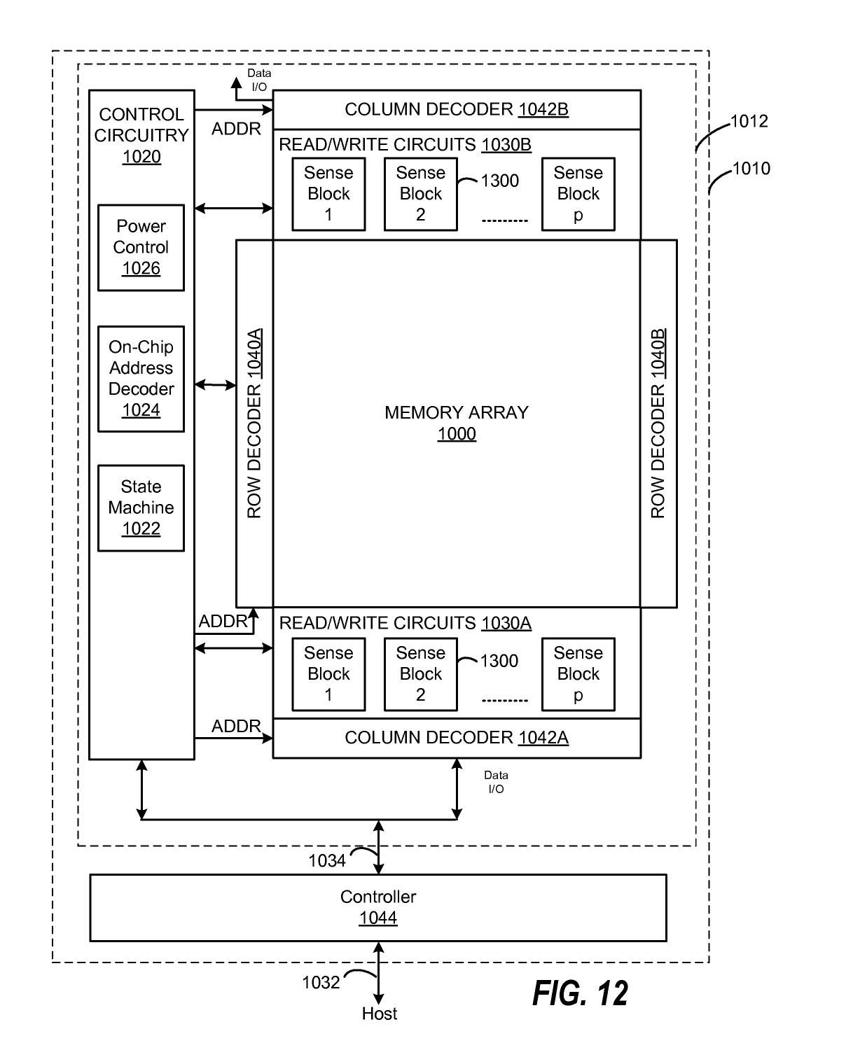

FIG. 12 illustrates a non-volatile storage device 1010 that may include one or more memory die or chips 1012. Memory die 1012 includes an array (two-dimensional or three dimensional) of memory cells 1000, control circuitry 1020, and read/write circuits 1030A and 1030B. In one embodiment, access to the memory array 1000 by the various peripheral circuits is implemented in a symmetric fashion, on opposite sides of the array, so that the densities of access lines and circuitry on each side are reduced by half. The read/write circuits 1030A and 1030B include multiple sense blocks 1300 which allow a page of memory cells to be read or programmed in parallel. The memory array 1000 is addressable by word lines via row decoders 1040A and 1040B and by bit lines via column decoders 1042A and 1042B. In a typical embodiment, a controller 1044 is included in the same memory device 1010 (e.g., a removable storage card or package) as the one or more memory die 1012. Commands and data are transferred between the host and controller 1044 via lines 1032 and between the controller and the one or more memory die 1012 via lines 1034. One implementation can include multiple chips 1012.

Control circuitry 1020 cooperates with the read/write circuits 1030A and 1030B to perform memory operations on the memory array 1000. The control circuitry 1020 includes a state machine 1022, an on-chip address decoder 1024 and a power control module 1026. The state machine 1022 provides chip-level control of memory operations. The on-chip address decoder 1024 provides an address interface to convert between the address that is used by the host or a memory controller to the hardware address used by the decoders 1040A, 1040B, 1042A, and 1042B. The power control module 1026 controls the power and voltages supplied to the word lines and bit lines during memory operations. In one embodiment, power control module 1026 includes one or more charge pumps that can create voltages larger than the supply voltage.

In one embodiment, one or any combination of control circuitry 1020, power control circuit 1026, decoder circuit 1024, state machine circuit 1022, decoder circuit 1042A, decoder circuit 1042B, decoder circuit 1040A, decoder circuit 1040B, read/write circuits 1030A, read/write circuits 1030B, and/or controller 1044 can be referred to as one or more managing circuits.

In one embodiment, an array of memory cells 1000 is divided into a large number of blocks (e.g., blocks 0-1023, or another amount) of memory cells. As is common for flash EEPROM systems, the block is the unit of erase. That is, each block contains the minimum number of memory cells that are erased together. Other units of erase can also be used. A block contains a set of NAND strings which are accessed via bit lines and word lines. Typically, all of the NAND strings in a block share a common set of word lines.

Each block is typically divided into a number of pages. In one embodiment, a page is a unit of programming. Other units of programming can also be used. One or more pages of data are typically stored in one row of memory cells. For example, one or more pages of data may be stored in memory cells connected to a common word line. Thus, in one embodiment, the set of memory cells that are connected to a common word line are programmed simultaneously. A page can store one or more sectors. A sector includes user data and overhead data (also called system data). Overhead data typically includes header information and Error Correction Codes (ECC) that have been calculated from the user data of the sector. The controller (or other component) calculates the ECC when data is being programmed into the array, and also checks it when data is being read from the array. Alternatively, the ECCs and/or other overhead data are stored in different pages, or even different blocks, than the user data to which they pertain. A sector of user data is typically 512 bytes, corresponding to the size of a sector in magnetic disk drives. A large number of pages form a block, anywhere from 8 pages, for example, up to 32, 64, 128 or more pages. Different sized blocks, pages and sectors can also be used.

The operation of a shared bit line structure described above is very similar to the operation of prior art flash memory. For example when reading memory cells, any suitable processing known in the art can be utilized. The deviation from processes known in the art are due to the presence of two select gate signals. If reading memory cells on NAND strings electrically connected to SGDE, then SGDE should be set at a voltage that turns on the selection gate (should use a voltage that is greater than the threshold voltage of selection gate, e.g., three volts) and SGDO should be set at zero volts to cut off those NAND strings that are electrically connected to SGDO. If reading memory cells connected on NAND strings electrically connected to SGDO, then SGDO receives the voltage to turn on the selection gate (e.g. three volts) and SGDE is set at zero volts to cut off the other NAND strings. The rest of the signals operate the same as is known in the art. When performing an erase operation, SGDE, SGDO, SGS, bit lines and source lines are floating. All word lines in a selected block are grounded. The p-well is provided with an appropriate erase voltage. Other erase schemes in the existing art can also be used. Additional details regarding shared bit line operation, can be found in U.S. patent application Ser. No. 13/107,686 referenced above.

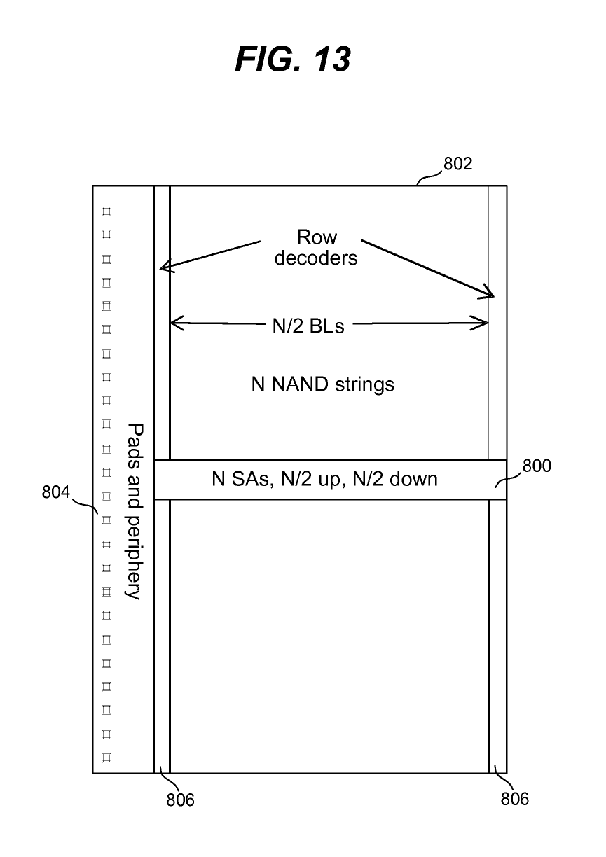

FIG. 13 depicts a memory architecture where the sense amplifiers are placed in the middle of the memory array. For example, FIG. 13 shows the sense amplifiers in middle region 800 of memory array 802. Contact pads and peripheral circuits are depicted in region 804 and row decoders are positioned in areas 806. In one embodiment, half of the sense amplifiers are connected to a plane of blocks of memory cells above and the other half of the sense amplifiers are connected to a plane of blocks of memory cells below the sense amplifiers. The embodiment of FIG. 13 allows for bit line lengths to be decreased by a factor of two. As a result, bit line resistance and capacitance is reduced by factor of two. The bit line RC time constant is reduced by a factor of 4. The embodiment of FIG. 13 has the additional advantage of further reducing the bit line RC time constant by virtue of doubling bit line pitch.

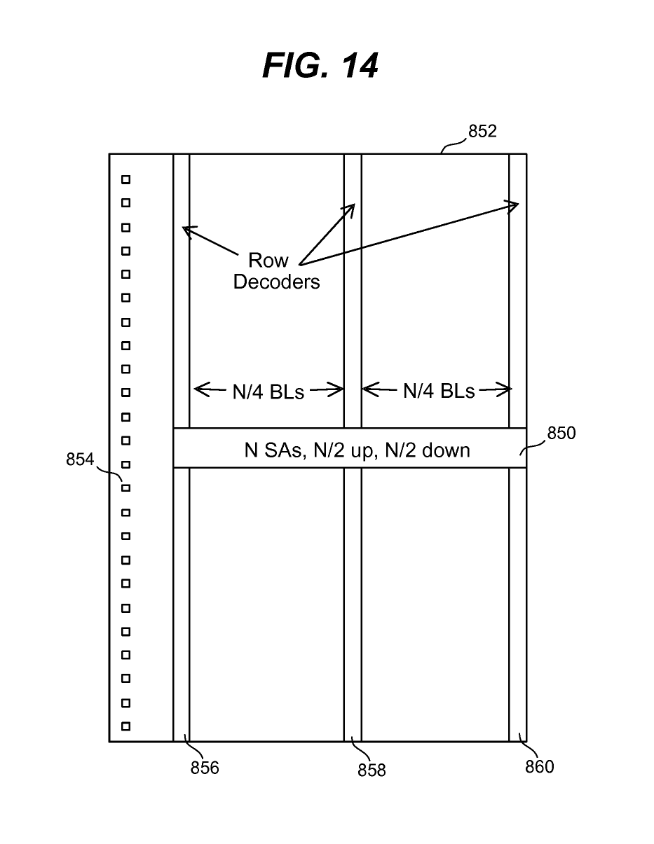

The embodiments described above have one bit line for every pair of NAND strings. This doubles the pitch of the bit lines allowing for further reduction of bit line capacitance, resistance, and/or both, depending on new width and spacing of bit lines. With bit line time constants reduced substantially, further performance gain can be achieved by adding another shared row decoder to make word lines half the usual length and, thereby, reducing word line time constants also by a factor of 4. Such an embodiment is depicted in FIG. 14, which shows sense amplifiers in middle region 850 of memory array 852, contact pads and peripheral circuits are depicted in region 854, and row decoders are positioned in areas 856, 858 and 860. Areas 856 and 860 are on the side of the memory array. Area 858 is in the center of the memory array. This shared row decoder will add to die size, but depending on the application, this added cost may be warranted by the increase in performance.

With no lock out mode (a memory cell locked out from further programming) and faster bit lines, the shared bit line architecture mode provides maximum advantage in terms of energy savings. No lock out allows all bit lines to be charged up simultaneously and also discharged simultaneously. This has a very large impact in saving energy needed to charge and discharge bit lines. The advantage of no lock out or of fewer lock out operations than is typically performed are explained in U.S. Pat. No. 7,489,553 titled “Non-Volatile Memory With Improved Sensing Having Bit-Line Lockout Control;” U.S. Pat. No. 7,492,640 titled “Sensing With Bit-Line Lockout Control In Non-Volatile Memory;” U.S. Pat. No. 7,808,832 titled “Non-Volatile Memory With Improved Sensing Having Bit-Line Lockout Control,” which are all incorporated herein by reference in their entirety.

In the above-described embodiment, the drain side selection gate is split into EVEN and ODD on the drain side. However, the dual selection signal architecture can be used on the source side too (or instead of on the drain side). In such an embodiment, there would be two source side selection signals SGSE and SGSO. SGDE and SGSE are connected to even NAND strings. SGDO and SGSO are connected to odd NAND Strings. One potential benefit is that in the embodiments above, the systems reads the even NAND strings first and then the odd NAND strings (or vice versa). When even NAND strings are being read, due to high voltage on unselected WLs (Vread), the memory cells on odd NAND string can get disturbed due to undesired electron injection/ejection. When odd NAND strings are being read, due to high voltage on unselected WLs (Vread), the threshold voltage of memory cells on even NAND string can shift due to undesired electron injection/ejection. By using the split source side selection gate, this undesirable shift of threshold voltage of memory cells on NAND strings not being read can be lowered. When the system reads even NAND strings, SGDE and SGSE are ON (Vsg). But the SGDO and SGSO are off (0V). With the two odd select gates off, the AA (Si) of odd NAND Strings is isolated. When the word lines are driven to VREAD while reading even NAND strings, it will boost the channel of odd NAND strings. As a result, the vertical field seen by odd NAND strings is lowered and undesirable shift of threshold voltage of memory cells on odd NAND strings while reading even NAND strings is mitigated.

Various features and techniques have been presented with respect to the NAND flash memory architecture. It will be appreciated from the provided disclosure that implementations of the disclosed technology are not so limited. By way of non-limiting example, embodiments in accordance with the present disclosure can provide and be used in the fabrication of a wide range of semiconductor devices, including but not limited to logic arrays, volatile memory arrays including SRAM and DRAM, and non-volatile memory arrays including both the NOR and NAND architecture.

One embodiment includes a fabrication process for non-volatile storage that includes forming a first control gate layer over a surface of a substrate at a memory region and a peripheral region, removing the first control gate layer from the memory region and after removing the first control gate layer from the memory region, forming a layer stack over the surface of the substrate including a tunnel dielectric layer, a charge storage layer, an intermediate dielectric layer, and a second control gate layer. The process then includes etching in a row direction to form from the layer stack a first plurality of layer stack columns at the memory region, a second plurality of layer stack columns at the peripheral region, and a plurality of isolation regions in the substrate between active areas underlying each layer stack column, forming a third control gate layer after etching the layer stack, etching in a column direction. Etching in the column direction forms: from the third control gate layer, a plurality of word lines at the memory region and a plurality of peripheral select lines at the peripheral region; from each layer stack column of the first plurality, a plurality of memory cells including a charge storage element and a control gate formed from the second control gate layer, each word line contacting a row of control gates from the first plurality of layer stack columns; and from each layer stack column of the second plurality, a plurality of transistors including a peripheral gate formed from the first control gate layer and the second control gate layer, each peripheral select line contacting a row of peripheral gates.

One embodiment includes a method of fabricating non-volatile storage that includes etching to form a first layer stack column including a first strip of a tunnel dielectric layer, a first strip of a charge storage layer over the first strip of the tunnel dielectric layer, a first strip of an intermediate dielectric layer over the first strip of the charge storage layer and a first strip of a first control gate layer over the first strip of the intermediate dielectric layer. Then method then includes forming an insulating layer over the first control gate layer and providing a first passageway through the insulating layer to the first strip of the first control gate layer, forming a second control gate layer over the insulating layer and in the first passageway, etching the first layer stack column to form a first select gate including the first passageway, and etching the second control gate layer to form a first select line and a second select line. The first select line contacts the first passageway to put the first select line in electrical communication with the first strip of the control gate layer for the select gate. The second select line is electrically insulated from the first passageway and the first strip of the first control gate layer for the first select gate.

One embodiment includes a non-volatile storage system comprising a first layer stack column including a first strip of a tunnel dielectric layer, a first strip of a charge storage layer over the first strip of the tunnel dielectric layer, a first strip of an intermediate dielectric layer over the first strip of the charge storage layer and a first strip of a first control gate layer over the first strip of the intermediate dielectric layer. The system further comprises an insulating layer over the first control gate layer having a first passageway therein through to the first strip of the first control gate layer, a second control gate layer overlying the insulating layer and filling the first passageway, a first select gate including the first passageway, and a first select line and a second select line formed form the second control gate layer. The first select line contacts the first passageway to put the first select line in electrical communication with the first strip of the control gate layer for the first select gate and the second select line is electrically insulated from the first passageway and the first strip of the first control gate layer for the first select gate.

The foregoing detailed description has been presented for purposes of illustration and description. It is not intended to be exhaustive or to limit the subject matter claimed herein to the precise form(s) disclosed. Many modifications and variations are possible in light of the above teachings. The described embodiments were chosen in order to best explain the principles of the disclosed technology and its practical application to thereby enable others skilled in the art to best utilize the technology in various embodiments and with various modifications as are suited to the particular use contemplated. It is intended that the scope of the invention be defined by the claims appended hereto.

What is claimed is:

1. A method of fabricating non-volatile storage, comprising:
forming a first control gate layer over a surface of a substrate at a memory region and a peripheral region;
removing the first control gate layer from the memory region;
after removing the first control gate layer from the memory region, forming a layer stack over the surface of the substrate including a tunnel dielectric layer, a charge storage layer, an intermediate dielectric layer, and a second control gate layer;
etching in a row direction to form from the layer stack a first plurality of layer stack columns at the memory region, a second plurality of layer stack columns at the peripheral region, and a plurality of isolation regions in the substrate between active areas underlying each layer stack column;
forming a third control gate layer after etching the layer stack; and
etching in a column direction;
wherein etching in the column direction forms from the third control gate layer, a plurality of word lines at the memory region and a plurality of peripheral select lines at the peripheral region;
wherein etching in the column direction forms from each layer stack column of the first plurality, a plurality of memory cells including a charge storage element and a control gate formed from the second control gate layer, each word line contacting a row of control gates from the first plurality of layer stack columns; and
wherein etching in the column direction forms from each layer stack column of the second plurality, a plurality of transistors including a peripheral gate formed from the first control gate layer and the second control gate layer, each peripheral select line contacting a row of peripheral gates.

2. A method according to claim 1, wherein:
etching in the column direction includes forming from the third control gate layer a first select line and a second select line;
etching in the column direction includes forming a select gate for each layer stack column of the first plurality; and
the first plurality of layer stack columns includes a first layer stack column having a first select gate.

3. A method according to claim 2, further comprising:
before forming the third control gate layer, forming an insulating layer at the memory region and providing a first passageway through the insulating layer to a strip of the second control gate layer for the first layer stack column;
wherein forming the third control gate layer comprises filling the first passageway before etching in the column direction.

4. A method according to claim 3, wherein:
the first select line contacts the first passageway to put the first select line in electrical communication with the strip of the second control gate layer for the first select gate, the second select line being electrically insulated from the first passageway and the strip of the second control gate layer for the first select gate.

5. A method according to claim 4, wherein:
the first plurality of layer stack columns includes a second layer stack column having a second select gate;
the method further comprises providing a second passageway through the insulating layer to a strip of the second control gate layer for the second layer stack column;
forming the third control gate layer comprises filling the second passageway before etching in the column direction;
the first select line is electrically insulated from the second passageway and the strip of the second control gate layer for the second select gate; and
the second select line contacts the second passageway to put the second select line in electrical communication with the strip of the second control gate layer for the second select gate.

6. A method of fabricating non-volatile storage comprising:
etching to form a first layer stack column including a first strip of a tunnel dielectric layer, a first strip of a charge storage layer over the first strip of the tunnel dielectric layer, a first strip of an intermediate dielectric layer over the first strip of the charge storage layer and a first strip of a first control gate layer over the first strip of the intermediate dielectric layer;
forming an insulating layer over the first control gate layer and providing a first passageway through the insulating layer to the first strip of the first control gate layer;
forming a second control gate layer over the insulating layer and in the first passageway;
etching the first layer stack column to form a first select gate including the first passageway; and
etching the second control gate layer to form a first select line and a second select line, the first select line contacting the first passageway to put the first select line in electrical communication with the first strip of the control gate layer for the select gate, the second select line being electrically insulated from the first passageway and the first strip of the first control gate layer for the first select gate.

7. A method according to claim 6, further comprising:
etching to form a second layer stack column including a second strip of the tunnel dielectric layer, a second strip of the charge storage layer over the second strip of the tunnel dielectric layer, a second strip of the intermediate dielectric layer over the second strip of the charge storage layer and a second strip of the first control gate layer over the second strip of the intermediate dielectric layer;
providing a second passageway through the insulating layer to the second strip of the first control gate layer of the second layer stack column; and
etching the second layer stack column to form a second select gate including the second passageway;
wherein the second control gate layer is formed in the second passageway;
wherein the first select line is insulated from the second passageway and the second strip of the first control gate layer for the second select gate; and
wherein the second select line contacts the second passageway to put the second select line in electrical communication with the second strip of the first control gate layer for the second select gate.

8. A method according to claim 7, further comprising:
etching to form a third layer stack column including a third strip of the tunnel dielectric layer, a third strip of the charge storage layer over the third strip of the tunnel dielectric layer, a third strip of the intermediate dielectric layer over the third strip of the charge storage layer and a third strip of the first control gate layer over the third strip of the intermediate dielectric layer; and
etching the third layer stack column to form a third select gate including the first passageway;
wherein the first passageway extends through the insulating layer to the third strip of the first control gate layer;
wherein the first select line contacts the first passageway to put the second select line in electrical communication with the third strip of the first control gate layer for the third select gate; and
wherein the second select line is insulated from the first passageway and the third strip of the first control gate layer for the third select gate.

9. A method according to claim 8, further comprising:
connecting the first select gate and the second select gate to a first bit line; and
connecting the third select gate to a second bit line.

10. A method according to claim 9, further comprising:
forming source/drain regions for the first select gate and the second select gate to connect the first select gate and the second select gate to the first bit line.

11. A method according to claim 10, wherein:
etching the first layer stack column comprises forming a first NAND string of non-volatile storage elements with the first select gate;
etching the second layer stack column comprises forming a second NAND string of non-volatile storage elements with the second select gate; and
etching the third layer stack column comprises forming a third NAND string of non-volatile storage elements with the third select gate.

12. A method according to claim 11, wherein:
each non-volatile storage element of the first NAND string includes a charge storage element and a control gate formed from the first control gate layer;
each non-volatile storage element of the second NAND string includes a charge storage element and a control gate formed from the first control gate layer; and
each non-volatile storage element of the third NAND string includes a charge storage element and a control gate formed from the first control gate layer.

13. A method according to claim 12, wherein etching the second control gate layer comprises:
forming a plurality of word lines, each word line contacting a row of non-volatile storage elements including one non-volatile storage element from each NAND string.

14. A non-volatile storage system, comprising:
a first layer stack column including a first strip of a tunnel dielectric layer, a first strip of a charge storage layer over the first strip of the tunnel dielectric layer, a first strip of an intermediate dielectric layer over the first strip of the charge storage layer and a first strip of a first control gate layer over the first strip of the intermediate dielectric layer;
an insulating layer over the first control gate layer having a first passageway therein through to the first strip of the first control gate layer;
a second control gate layer overlying the insulating layer and filling the first passageway;
a first select gate including the first passageway; and
a first select line and a second select line formed form the second control gate layer, the first select line contacting the first passageway to put the first select line in electrical communication with the first strip of the control gate layer for the first select gate, the second select line being electrically insulated from the first passageway and the first strip of the first control gate layer for the first select gate.

15. A non-volatile memory system according to claim 14, further comprising:
a second layer stack column including a second strip of the tunnel dielectric layer, a second strip of the charge storage layer over the second strip of the tunnel dielectric layer, a second strip of the intermediate dielectric layer over the second strip of the charge storage layer and a second strip of the first control gate layer over the second strip of the intermediate dielectric layer; and
a second passageway through the insulating layer to the second strip of the first control gate layer of the second layer stack column;
wherein the second layer stack column includes a second select gate including the second passageway;
wherein the second control gate layer is formed in the second passageway;
wherein the first select line is insulated from the second passageway and the second strip of the first control gate layer for the second select gate; and
wherein the second select line contacts the second passageway to put the second select line in electrical communication with the second strip of the first control gate layer for the second select gate.

16. A non-volatile memory system according to claim 15, further comprising:
a first bit line connected to the first select gate and the second select gate; and
a second bit line connected to the third select gate.

17. A non-volatile memory system according to claim 16, further comprising:
a first source/drain region connecting the first select gate to the first bit line; and
a second source/drain region connecting the second select gate to the first bit line.

18. A non-volatile memory system according to claim 17, wherein:
the first layer stack column comprises a first NAND string of non-volatile storage elements with the first select gate;
the second layer stack column comprises a second NAND string of non-volatile storage elements with the second select gate; and
the third layer stack column comprises a third NAND string of non-volatile storage elements with the third select gate.

19. A non-volatile memory system according to claim 18, wherein:
each non-volatile storage element of the first NAND string includes a charge storage element and a control gate formed from the first control gate layer;
each non-volatile storage element of the second NAND string includes a charge storage element and a control gate formed from the first control gate layer; and
each non-volatile storage element of the third NAND string includes a charge storage element and a control gate formed from the first control gate layer.

20. A non-volatile memory system according to claim 19, wherein the second control gate layer comprises:
a plurality of word lines, each word line contacting a row of non-volatile storage elements including one non-volatile storage element from each NAND string.

21. A non-volatile memory system according to claim 14, wherein the charge storage layer includes a nanostructure coating.

22. A non-volatile memory system according to claim 21, wherein the nano-structure coating includes metallic nanodots.
